(19) United States
(12) Patent Application Publication
(10) Pub. No.: US 2024/0364276 A1
(43) Pub. Date: Oct. 31, 2024

(54) METHODS AND APPARATUS FOR DYNAMIC DIGITAL PRE-DISTORTION CORRECTION

(71) Applicant: Texas Instruments Incorporated, Dallas, TX (US)

(72) Inventors: Chandrasekhar Sriram, Bangalore (IN); Sarma Sundareswara Gunturi, Bangalore (IN); Jawaharlal Tangudu, Bangalore (IN); Harshit Moondra, Bangalore (IN); Harsh Garg, Tukhmirpur (IN); Sanjay Pennam, Visakhapatnam (IN)

(21) Appl. No.: 18/648,037

(22) Filed: Apr. 26, 2024

(30) Foreign Application Priority Data
Apr. 28, 2023 (IN) 202341030532

(51) Int. Cl. H03F 1/32; H03F 3/24

(52) U.S. Cl. CPC H03F 1/3241; H03F 3/245; H03F 2200/451

(57) ABSTRACT

Methods, apparatus, systems, and articles of manufacture are described for dynamic digital pre-distortion correction. An example system includes programmable circuitry operable to execute computer readable instructions to at least: generate signal statistics based on an input signal; group the signal statistics into a first group of signal statistics or a second group of signal statistics based on time constants of the signal statistics; decimate the first group of signal statistics; generate a first predistortion term based on the decimated first group of signal statistics; generate a second predistortion term based on the second group of signal statistics; and generate an output predistortion terminal based on the first predistortion term and the second predistortion term.

### RELATED APPLICATIONS

This patent application claims the benefit of and priority to Indian Provisional Patent Application No. 202341030532 filed Apr. 28, 2023, which application is hereby incorporated herein by reference in its entirety.

### TECHNICAL FIELD

This description relates generally to circuitry, and, more particularly, to methods and apparatus for dynamic digital pre-distortion correction.

### BACKGROUND

Transmitters are electrical devices that transmit, project, or output wireless signals that can be obtained by other devices. For example, transmitters can include power amplifiers to amplify a low power radio frequency (RF) signal. Transmitters are used in a wide range of fields including medical imaging, telecommunications, data transfer, and other fields that utilize analog signals. For example, in telecommunications, a base station may include a power amplifier to transmit a cellular signal.

### SUMMARY

For dynamic digital pre-distortion correction, an example apparatus includes signal statistics generator circuitry having an input, a first output, and a second output; decimation circuitry having an input and an output, the input of the decimation circuitry is coupled to the first output of the signal statistics generator circuitry; first dynamics term generator circuitry having a first input, a second input, and an output, the first input of the first dynamics term generator circuitry coupled to the output of the decimation circuitry, the second input coupled to the input of the signal statistics generator circuitry; second dynamics term generator circuitry having a first input a second input and an output, the first input coupled to the second output of the signal statistics generator circuitry, the second input coupled to the input of the signal statistics generator circuitry; and summation circuitry having a first input and a second input, the first input coupled to the output of the first dynamics term generator circuitry, the second input coupled to the output of the second dynamics term generator circuitry. Other examples are described.

For dynamic digital pre-distortion correction, an example apparatus includes For correcting non-linearity in amplifiers, an example apparatus includes memory; and programmable circuitry operable to execute computer readable instructions to at least: generate signal statistics based on an input signal; group the signal statistics into a first group of signal statistics or a second group of signal statistics based on time constants of the signal statistics; decimate the first group of signal statistics; generate a first predistortion term based on the decimated first group of signal statistics; generate a second predistortion term based on the second group of signal statistics; and generate an output predistortion terminal based on the first predistortion term and the second predistortion term. Other examples are described.

For dynamic digital pre-distortion correction, an example transmitter includes a host device having an output; interpolation circuitry having an input and an output, the input of the interpolation circuitry coupled to the output of the host device; a predistortion correction circuitry including: signal statistics generator circuitry having an input, a first output, and a second output, the input of the signal statistics generator circuitry coupled to the output of the interpolation circuitry; decimation circuitry having an input and an output, the input of the decimation circuitry is coupled to the first output of the signal statistics generator circuitry; first dynamics term generator circuitry having a first input, a second input, and an output, the first input of the first dynamics term generator circuitry coupled to the output of the decimation circuitry, the second input coupled to the input of the signal statistics generator circuitry; second dynamics term generator circuitry having a first input a second input and an output, the first input coupled to the second output of the signal statistics generator circuitry, the second input coupled to the input of the signal statistics generator circuitry; and summation circuitry having a first input, a second input, and an output, the first input coupled to the output of the first dynamics term generator circuitry, the second input coupled to the output of the second dynamics term generator circuitry; digital circuitry having an input and an output, the input of the digital circuitry coupled to the output of the summation circuitry; a digital-to-analog converter having an input and an output, the input of the digital-to-analog converter coupled to the output of the digital circuitry; and a power amplifier having an input and an output, the input of the power amplifier coupled to the output of the digital-to-analog converter. Other examples are described.

### BRIEF DESCRIPTION OF THE DRAWINGS

FIG. 1 is an example block diagram of a base station with integrated digital pre-distortion (DPD) correction.

FIG. 2 is an example block diagram including an example of a first DPD corrector in parallel with a second DPD corrector.

FIG. 3 is an example block diagram including an example of the second DPD corrector circuitry of FIG. 1, the second DPD corrector including a term generator and a signal statistics circuit.

FIG. 4A is an example block diagram of the second DPD corrector circuitry of FIGS. 1-3.

FIG. 4B is an example block diagram of one of the dynamic DPD term generator circuitries of FIG. 4A.

FIG. 5 is a flowchart representative of example machine readable instructions or example operations that may be executed, instantiated, or performed by example programmable circuitry to implement the second DPD corrector circuitry of FIG. 1-4B.

FIG. 6A is an alternative example block diagram of the second DPD corrector circuitry of FIGS. 1-3.

FIG. 6B is an example block diagram of one of the dynamic DPD term generator circuitries of FIG. 6A.

FIG. 7 is a flowchart representative of example machine readable instructions or example operations that may be executed, instantiated, or performed by example programmable circuitry to implement the second DPD corrector circuitry of FIG. 1-3, 6A, or 6B.

FIG. 8 is an alternative example block diagram of the second DPD corrector circuitry of FIGS. 1-3.

FIG. 9 is an example block diagram of the slow dynamic term generator circuitry of FIG. 8.

FIG. 10 is an example circuit diagram of one of the time varying coefficients pre-combiner circuitries of FIG. 9.

FIG. 11 is an example block diagram of the fast dynamic term generator circuitry of FIG. 8.

FIG. 12 is an example block diagram of the slow dynamic term generator circuitry of FIG. 8 accounting for historic input data.

FIG. 13 is an example block diagram of the fast dynamic term generator circuitry of FIG. 8 accounting for historic input data.

FIG. 14 is an example block diagram of the signal statistics sub-circuitry of FIG. 3.

FIGS. 15-16 are flowcharts representative of example machine readable instructions or example operations that may be executed, instantiated, or performed by example programmable circuitry to implement the second DPD corrector circuitry of FIG. 1-3 or 8-14.

FIG. 17 is a block diagram of an example processing platform including programmable circuitry structured to execute, instantiate, or perform the example machine readable instructions or perform the example operations of FIGS. 5, 6, 15, and 16 to implement the second DPD corrector circuitry of FIG. 1-4B, 6A, 6B, or 8-14.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines or boundaries may be idealized. In reality, the boundaries or lines may be unobservable, blended or irregular.

A power amplifier (PA) may be used in a transmit (Tx) signal chain to amplify low power radio frequency (RF) signals. For example, a base station includes a Tx signal chain with a PA for transmitting cellular signals. The base station may transmit cellular signals to user equipment (UE), which may be a smartphone, laptop, tablet, or other type of device with cellular capabilities. The base station and the UE may operate in with a cellular standard, such as 4^{th} generation (4G) long-term evolution (LTE), 5^{th} generation (5G) new radio (NR), etc.

A base station can implement techniques such as beamforming and massive multiple-input multiple-output (MIMO) to increase data throughput and reliability while communicating with the UE. For example, a base station may include a large number of antenna elements, and consequently, a large number of Tx chains. To compensate for increased power draw from the large number of Tx chains, increasing the power efficiency of the Tx chains may be desired. For example, the power efficiency of the PA within the Tx chain may be increased by using Gallium Nitride (GaN) technology. A GaN device may be more power efficient than a comparable silicon device due to the larger bandgap of GaN relative to silicon. However, a GaN PA may experience effects such as electron trapping and de-trapping (e.g., within the GaN material), which can cause distortion at the output of the GaN PA.

Examples described herein include Tx architecture for digital pre-distortion (DPD) correction to compensate for the signal dynamics of GaN PAs. Examples described herein include dynamic DPD corrector circuitry to generate long-term signal statistics that model the GaN trapping and de-trapping effectors. Also, examples described herein generate nonlinear (NL) terms based on a feedback loop that measures the NL of the GaN PA. Examples described herein provide techniques for combining the signal statistics with the NL terms to adjust the input data signal to mitigate the NL introduced by the GaN PA. Accordingly, examples described herein correct for non-linearity or other signal dynamics of GaN PAs to increase the strength of a transmitted signal, reduce undesired characteristics of a transmitted signal, or improve linearity.

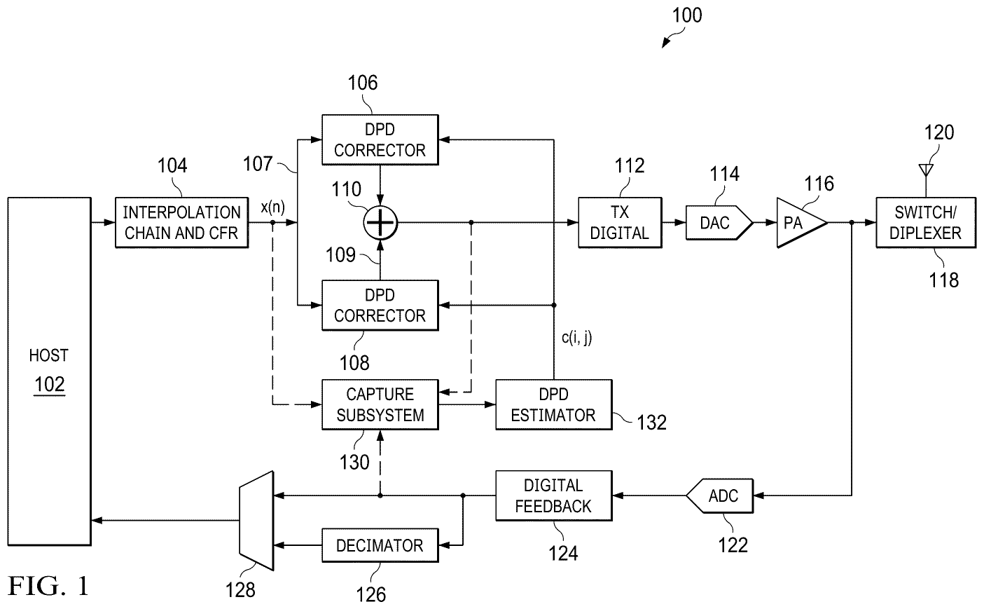

FIG. 1 illustrates example circuitry 100 of a Tx signal chain that may be implemented in at least one of a base station, a transmitter, or a transceiver. The circuitry 100 includes an example host device 102, example interpolation chain circuitry 104, first example DPD corrector circuitry 106, example second DPD corrector circuitry 108, example summation circuitry 110, example Tx digital circuitry 112, an example digital-to-analog converter (DAC) 114, an example PA 116, an example switch/diplexer 118, an example antenna 120, an example analog to digital converter (ADC) 122, example digital feedback circuitry 124, example decimator circuitry 126, an example multiplexer 128, an example capture subsystem 130, and example DPD estimator circuitry 132. The example circuitry 100 could implement a high performance zero-intermediate frequency (IF) or radio frequency (RF) sampling transceiver.

The host 102 of FIG. 1 has an output coupled to the interpolation chain circuitry 104 and an input coupled to the multiplexer 128. The interpolation chain circuitry 104 has an input coupled to the output of the host 102 and an output coupled to the DPD corrector circuitries 106, 108 and the capture subsystem 130. The DPD corrector circuitry 106 has a first input (e.g., input 107) coupled to the output of the interpolation chain circuitry 104, a second input coupled to the DPD estimator circuitry 132, and an output coupled to the summation circuitry 110. The DPD corrector circuitry 108 has a first input 107 coupled to the output of the interpolation chain circuitry 104, a second input coupled to the DPD estimator circuitry 132, and an output 109 coupled to the summation circuitry 110. The summation circuitry 110 has a first input coupled to the output of the DPD corrector circuitry 106, a second input coupled to the output 109, and an output coupled to the TX digital circuitry 112.

The Tx digital circuitry 112 of FIG. 1 has an input coupled to the output of the summation circuitry 110 and an output coupled to the DAC 114. The DAC 114 has an input coupled to the output of the Tx digital circuitry 112 and an output coupled to the PA 116. The PA 116 has an input coupled to the output of the DAC 114 and an output coupled to the switch 118 and the ADC 122. The switch/diplexer 118 has an input coupled to the output of the PA 116 and an output coupled to the antenna 120. The antenna 120 is coupled to the output of the switch/diplexer 118.

The ADC 122 of FIG. 1 has an input coupled to the output of the PA 116 and an output coupled to the digital feedback circuitry 124. The digital feedback circuitry 124 has an input coupled to the output of the ADC 122 and an output coupled to the MUX 128, the decimator 126, and the capture subsystem 130. The decimator circuitry 126 has an input coupled to the output of the digital feedback circuitry 124 and an output couple to the MUX 128. The multiplexer 128 has a first input coupled to the output of the digital feedback circuitry 124, a second input coupled to the output of the decimator circuitry 126, and an output coupled to the input of the host 102.

The capture subsystem 130 of FIG. 1 has a first input coupled to the output of the interpolation chain circuitry 104, a second input coupled to the output of the summation circuitry 110, a third input coupled to the output of the digital feedback circuitry 124, and an output coupled the DPD estimator circuitry 132. The DPD estimator circuitry 132 has an input coupled to the output of the capture subsystem, and an output coupled to the second input of the DPD corrector circuitry 106 and coupled to the second input of the DPD corrector circuitry 108.

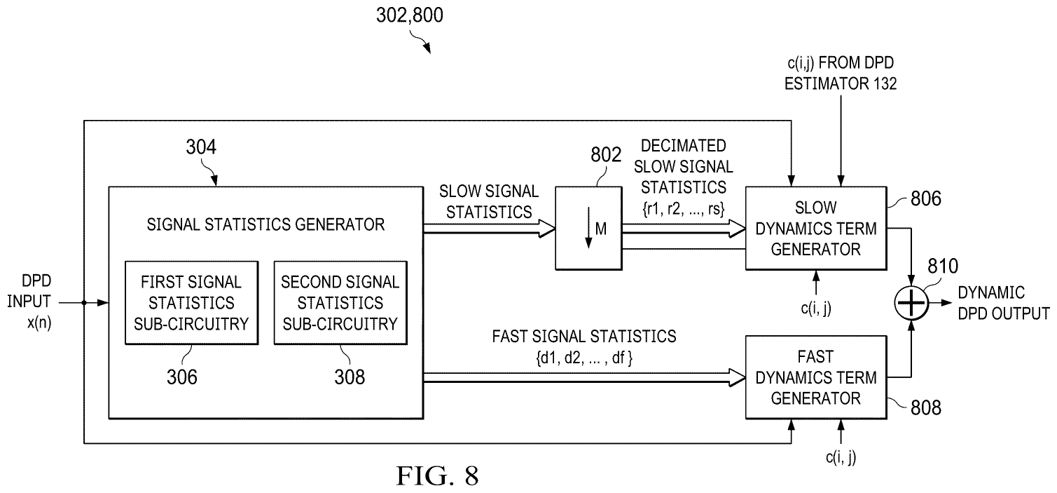

The host 102 of FIG. 1 is configured to provide a Tx signal at the output of the host 102. The interpolation chain circuitry 104 is configured to perform interpolation (e.g., upsampling) on the Tx signal. Optionally, the interpolation chain circuitry 104 may also perform Crest Factor Reduction (CFR) on the Tx signal. Although the host 102 and the interpolation chain circuitry 104 are illustrated as separate elements in the example of FIG. 8, in some examples, the interpolation chain circuitry 104 is part of the host 102, such that the host 102 is further configured to perform the operations of the described interpolation chain circuitry 104. However, the interpolation chain circuitry 104 may not be included in some systems or may be included in the host 102.

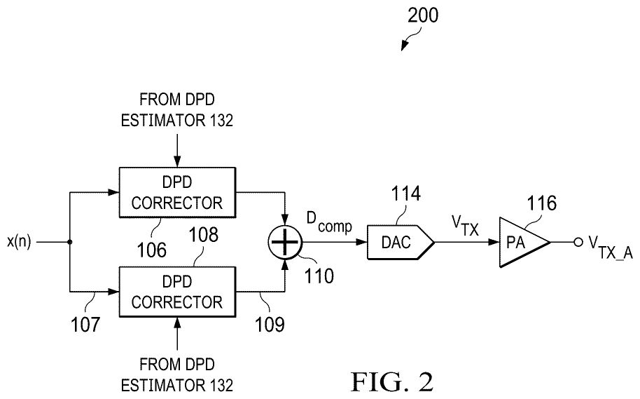

The DPD corrector circuitries 106, 108 of FIG. 1 may be configured to perform DPD correction on the input signal (x(n)) from the interpolation chain circuitry 104. As further described below, the DPD corrector circuitries 106, 108 pre-distort the input signal based on characteristics of the output signal from the PA 116 to mitigate the non-linearity of the PA 116. The DPD corrector circuitries 106, 108 obtain the characteristics of the output signal from the PA 116 via the DPD estimator circuitry 132 (e.g., via a feedback loop). The DPD corrector circuitries 106, 108 are further described below in conjunction with FIGS. 2-12. The signals output by the DPD corrector circuitries 106, 108 are combined by the summation circuitry 110, and the combined signal is provided at the output of the summation circuitry 110.

The Tx digital circuitry 112 of FIG. 1 is configured to perform digital signal processing on the signal received on the input of the Tx digital circuitry 112, for example, interpolation, upconverting, etc. The Tx digital circuitry 112 provides the processed digital signal at the output of the Tx digital circuitry 112 to the DAC 114, which converts the digital signal to an analog signal. The DAC 114 provides the analog signal at the output of the DAC 114 to the PA 116, which amplifies the signal. In some examples, the switch/diplexer 118 comprises a switch, and is configured to switch between Tx and Rx during time-division duplexing (TDD) operation. In alternative examples, the switch/diplexer 118 comprises a diplexer, which is used to isolate Tx and Rx signals during frequency division duplexing (FDD) operation. In both examples, the switch/diplexer 118 provides the signal to the antenna 120 for transmission (e.g., over an air interface).

The ADC 122 of FIG. 1 is configured to convert the analog signal received on the input of the ADC 122 to a digital signal, which is provided at the output of the ADC 122. The digital feedback circuitry 124 is configured to perform digital signal processing on the signal output by the ADC 122 which includes, for example, down converting the signal by the carrier frequency. The decimator circuitry 126 is configured to down sample a signal received on the input of the decimator circuitry 126 and provide the down sampled signal at the output of the decimator circuitry 126. The multiplexer 128 is configured to select a signal from the first and second inputs of the multiplexer 128 to be provided at the output of the multiplexer 128 to the host 102. In some examples, the multiplexer 128 may include a control input to control selection between the first and second inputs.

The capture subsystem 130 of FIG. 1 is configured to capture a block of samples in a time aligned fashion at the DPD input (e.g., of the DPD corrector circuitries 106, 108), the DPD output (e.g., of the DPD corrector circuitries 106, 108 or of the summation circuitry 110), and the feedback output (e.g., of the ADC 122). The samples are provided to the DPD estimator circuitry 132, which utilizes the samples to estimate coefficients (e.g., c(i, j)) to be used for DPD correction.

The DPD estimator circuitry 132 of FIG. 1 is configured to generate one or more terms (e.g., coefficients) based on the output of the capture subsystem 130. For example, the DPD estimator circuitry 132 can periodically (e.g., based on time, temperature, etc.) estimate the c(i,j) terms based on the DPD correction input, feedback output (e.g., corresponding to the output of the PA 116), and the output signal of the summation circuitry 110. In some examples, the DPD estimator circuitry 132 updates and estimates the terms in an iterative manner, such that the feedback output and the DPD input match. The one or more terms are DPD coefficients that correspond to the non-linearity generated by the PA 116. The one or more terms are provided to the second input of the DPD corrector circuitry 106 and the second input of the DPD corrector circuitry 108. In some examples, the DPD estimator circuitry 132 is configured to generate the one or more terms further based on one or more system parameters.

FIG. 2 illustrates an example circuitry 200 corresponding to a portion of the circuitry 100 of FIG. 1. The circuitry 200 includes the (first) DPD corrector circuitry 106, the (second) DPD corrector circuitry 108, the summation circuitry 110, the digital-to-analog converter (DAC) 114, and the power amplifier (PA) 116 of FIG. 1. However, additional components can be added or removed from the circuitry 200 of FIG. 2. For example, the TX digital circuitry 112 can be coupled between the output of the summation circuitry 110 and the input of the DAC 114.

The DPD corrector circuitry 106 of FIG. 2 has an input 107 and an output coupled to the summation circuitry 110. The DPD corrector circuitry 108 has an input 107 coupled to the input of the DPD corrector circuitry 106, and an output 109 coupled to the summation circuitry 110. The summation circuitry 110 has a first input coupled to the output of the DPD corrector circuitry 106, a second input coupled to the output 109 of the DPD corrector circuitry 108, and an output coupled to the DAC 114. The DAC 114 has an input coupled to the output of the summation circuitry 110 and an output coupled to the PA 116. The PA 116 has an input coupled to the output of the DAC 114 and an output coupled the switch 118 and the ADC 122. The DPD corrector circuitry 106 receives an input signal x(n) on the input of the DPD corrector circuitry 106, and the DPD corrector circuitry 108 receives the input signal x(n) on the input 107. The summation circuitry 110 provides a signal D_{comp} at the output of the summation circuitry 110, which is received at the input of the DAC 114. The DAC 114 provides a signal V_{Tx}, which is received on the input of the PA 116. The PA 116 provides the signal V_{Tx_A} at the output of the PA 116.

In some examples, the response of the PA 116 of FIG. 2 is non-linear. For example, the power of the signal V_{Tx_A} output by the PA 116 varies non-linearly with respect to the power of the signal V_{Tx} received on the input of the PA 116. The non-linearity of the PA 116 can be pre-compensated in the digital domain using the DPD corrector circuitry 106. For example, the DPD corrector circuitry 106 applies pre-compensation to the signal x(n) to produce the signal D_{comp}. The compensated signal D_{comp} and the non-linearity of the PA 116 effectively cancel with one another, resulting in the signal V_{Tx_A} that varies linearly with respect to the signal x(n). In some examples, the DPD corrector circuitry 106 applies the compensation by using a Generalized Memory Polynomial (GMP) model and one or more lookup tables (LUTs). The LUTs are a function of the input signal x(n) and may be pre-calibrated/pre-programmed with different values depending on a type (e.g., model) of the PA 116. For example, the GMP is modeled by the function y(n)x(n)+Σₖ₌₁^{N}^{_{LUT}}x(n−l₁(k))*LUT(|x(n−l₂(k)|), where y(n) is the GMP function, x(n) is the nth sample of x(n), l₁(k) and l₂(k) are functions representing first and second lags (e.g., delayed samples) of x(n), and N_{LUT} is the total number of LUTs. In some examples, the PA 116 is a GaN PA. Although the PA 116 will generally be referred to as a GaN PA in the present description, other suitable types of semiconductors (e.g., silicon) may also be used.

In some examples, electron trapping and de-trapping may occur within the GaN material of the PA 116 of FIG. 2, resulting in further non-linearity in the response of the PA 116 that is not compensated for by the DPD corrector circuitry 106. For example, variations in the power of the signal V_{Tx} can produce transients in the gain response of the GaN PA due to the electron trapping/de-trapping effects. Further, after the GaN PA transitions from OFF to ON, the GaN PA may experience transient effects (e.g., due to electron trapping/de-trapping), which can degrade metrics such as error vector magnitude (EVM) and adjacent channel leakage ratio (ACLR). Such transient effects are relevant with respect to time division duplex (TDD) in cellular communications, where the base station alternates between Tx and receive (Rx) over time, causing the PA 116 to alternate between ON and OFF. Transient effects may also occur during frequency division duplex (FDD) operation (e.g., due to variations in the power of the signal V_{Tx}).

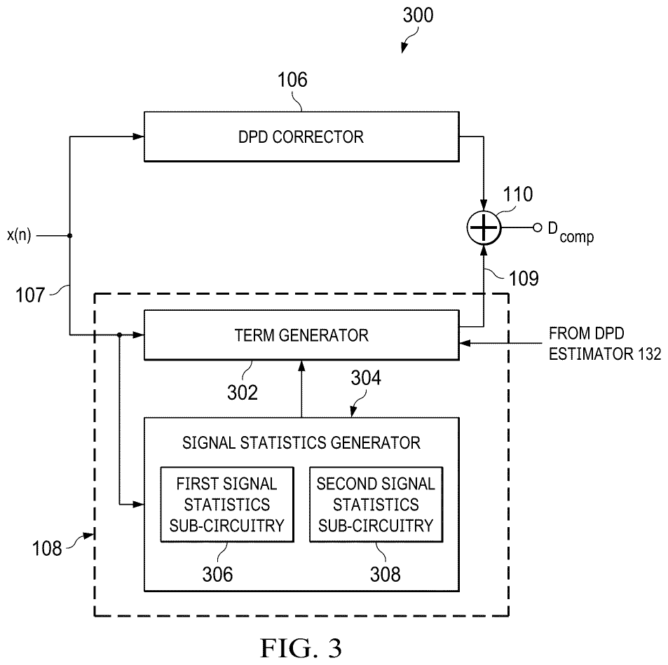

To compensate for the non-linearity caused by electron trapping/de-trapping within the GaN PA, the circuitry 200 of FIG. 2 further includes the DPD corrector circuitry 108 and the summation circuitry 110. The DPD corrector circuitry 108 is configured to generate statistics related to the signal x(n) over time and apply compensation to the signal x(n) based on the statistics. For example, the statistics are related to transients in the response of the GaN PA due to electron trapping/de-trapping effects. The output of the DPD corrector circuitry 108 is combined (e.g., added) with the output of the DPD corrector circuitry 106 to produce the compensated signal D_{comp}. The DPD corrector circuitry 108 is further described below in conjunction with FIGS. 3-16.

FIG. 3 illustrates example circuitry 300 including the DPD corrector circuitry 106, the DPD corrector circuitry 108, and the summation circuitry 110 of FIGS. 1-2. The DPD corrector circuitry 108 of FIG. 3 includes term generator circuitry 302 and signal statistics generator circuitry 304. The signal statistics generator circuitry 304 includes first signal statistics sub-circuitry 306 and a second signal statistics sub-circuitry 308. The term generator circuitry 302 has a first input coupled to the input 107, a second input, and an output coupled to the output 109. The signal statistics generator circuitry 304 has an input coupled to the input 107, and an output coupled to the second input of the term generator circuitry 302. In some examples, the DPD corrector circuitry 106, the DPD corrector circuitry 108, and the summation circuitry 110 are included on a same semiconductor substrate or “chip”.

The term generator circuitry 302 of FIG. 3 is configured to generate a set of terms based on the input signal x(n) at the first input of the term generator circuitry 302 and based on the set of statistics received from the signal statistics generator circuitry 304 at the second input of the term generator circuitry 302. The term generator circuitry 302 is further configured to combine the set of terms to produce a signal at the output 109. For example, the term generator circuitry 302 is configured to generate an output signal (e.g., yd(n)) that pre-distorts the input signal x(n) based on determined DPD coefficients (also referred to as DPD values) determined from a feedback loop. The output signal mitigates the nonlinearity generated by the PA 116 of FIGS. 1-2. In some examples, the output signal corresponds to the below Equation 1.

$${y}_{d} ( n ) = {\sum }_{i = 1}^{N} {\sum }_{j = 1}^{L} c ( i , j ) {t}_{i} {\vert x ( n ) \vert}^{j - 1} x ( n ) \qquad ( Equation 1 )$$

In the above Equation 1, c(i,j) corresponds to the DPD coefficients generated by the DPD estimator circuitry 132 of FIG. 1 via a feedback loop, ti corresponds to signal statistics generated by the signal statistics generator circuitry 304, N corresponds to the maximum number of signal statistics, and L corresponds to the total number of basis function that the system will support (e.g., maximum order of nonlinear of the PA 116 of FIG. 1). In some examples, the |x(n)|^{j-1} can be replaced by other basis polynomials, such as Zernike polynomial of degree of j, as shown in the below Equation 2.

$${y}_{d} ( n ) = {\sum }_{i = 1}^{N} {\sum }_{j = 1}^{L} c ( i , j ) {t}_{i} {BF}_{j} ( \vert x ( n ) \vert ) x ( n ) \qquad ( Equation 2 )$$

In the above Equation 2, BFⱼ(.) corresponds to a basis function.

The signal statistics generator circuitry 304 of FIG. 3 is configured to monitor the input signal x(n) at the input of the signal statistics generator circuitry 304 and generate statistics based on the monitoring of the signal x(n). The signal statistics generator circuitry 304 may be further configured to provide a set of statistics at the output of the signal statistics generator circuitry 304 based on the generated statistics. In some examples, each of the statistics are based on the input signal x(n) and one or more time delayed versions of the input signal x(n).

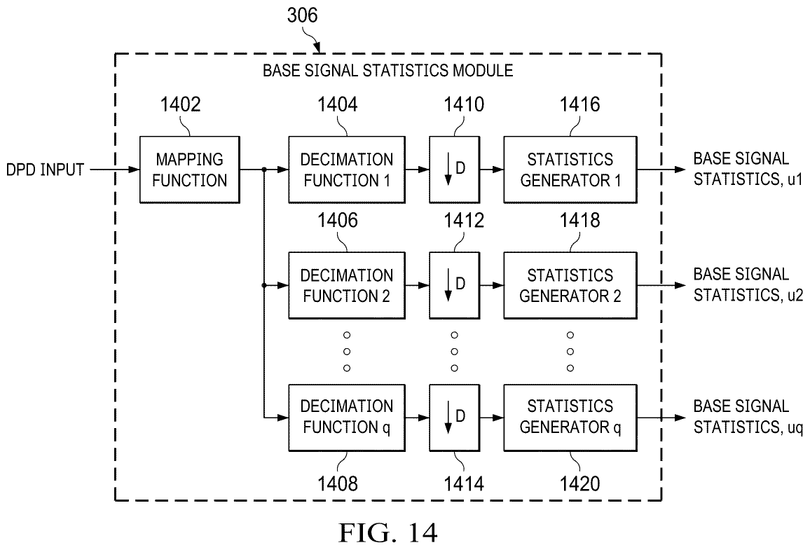

The signal statistics sub-circuitry 306 of FIG. 3 is configured to generate the first set of signal statistics based the signal x(n) received on the input of the signal statistics sub-circuitry 306. For example, the signal statistics sub-circuitry 306 generates the first set of signal statistics based on the input signal x(n) and one or more delayed samples of the input signal x(n). In some further examples, the signal statistics sub-circuitry 306 generates the first set of signal statistics based on absolute values of the input signal x(n) and the one or more delayed samples of the input signal x(n). Also, or alternatively, one or more sets of independent parameters may be configured, where a different set of independent parameters is used to generate each signal statistic u₁, u₂, . . . , u_{q} of the first set of signal statistics. The signal statistics sub-circuitry 306 is further described below in conjunction with FIG. 14.

The signal statistics sub-circuitry 308 of FIG. 3 is configured to generate the second set of signal statistics based on the first set of signal statistics. For example, the signal statistics sub-circuitry 308 generates each signal statistic v₁, v₂, . . . , Vᵣ of the second set of signal statistics based on a multiplication of one or more statistics of the first set of signal statistics. In one example, the signal statistics sub-circuitry 308 generates the signal statistics as v₁=u₁², v₂=u₁*u₂, etc. The one or more statistics to be multiplied may be selected from the first set of signal statistics based on a type of the PA (e.g., PA 116).

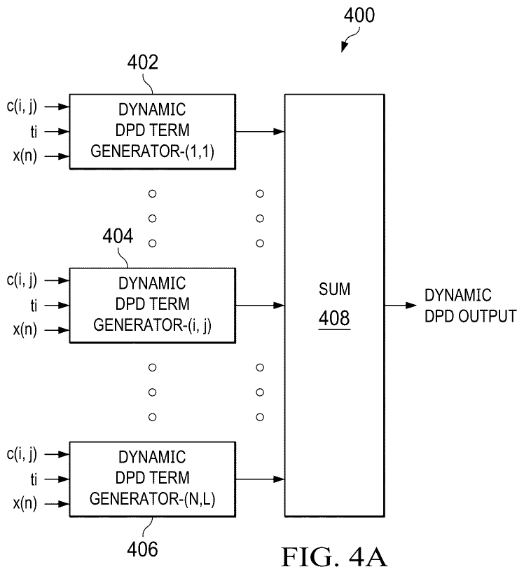

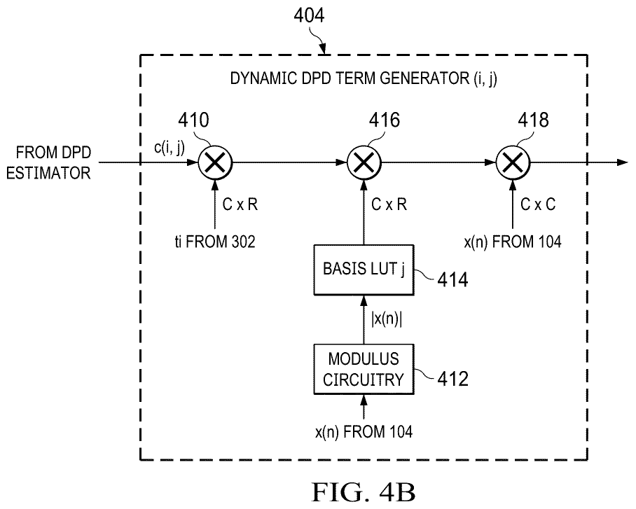

FIG. 4A is a block diagram 400 that corresponds to the term generator circuitry 302 of FIG. 3. The example block diagram 400 of FIG. 4A includes example dynamic DPD term generator circuitries 402, 404, 406 and example summation circuitry 408.

The dynamic DPD term generator circuitries 402, 404, 406 of FIG. 4A adjust an input signal to generate dynamic DPD terms that are all summed together to generate the dynamic DPD output y(n). For example, the dynamic DPD term generators circuitries 402, 404, 406 generate the (i,j)th dynamic DPD terms c(i, j) tᵢBFⱼ(|x(n)|)x(n), which are summed by the summation circuitry 408 to generate the dynamic DPD output corresponding to the above Equation 2. An example of one of the dynamic DPD term generator circuitries 402, 404, 406 is further described below in conjunction with FIG. 4B.

FIG. 4B is an example circuit implementation of the dynamic DPD term generator circuitry 404 of FIG. 4A. However, the circuit implementation of FIG. 4B could implement any of the dynamic DPD term generator circuitries 402, 404, 406. The DPD term generator circuitry 404 includes example multiplier circuitry 410, 416, 418, example modulus circuitry 412, and an example lookup table 414.

The multiplier circuitries 410, 416, 418 of FIG. 4B each include two inputs and an output. The first input of the multiplier circuitry 410 is coupled to the DPD estimator circuitry 132 of FIG. 1. The second input of the multiplier circuitry 410 is coupled to the signal statistics generator circuitry 304 of FIG. 3. The output of the multiplier circuitry 410 is coupled to the first input of the multiplier circuitry 416. The second input of the multiplier circuitry 416 is coupled to the output of the lookup table 414. The output of the multiplier circuitry 416 is coupled to the first input of the multiplier circuitry 418. The second input of the multiplier circuitry 418 is coupled to the output of the interpolation chain circuitry 104 of FIG. 1 and the input of the DPD corrector circuitry 106 of FIGS. 1-3.

The modulus circuitry 412 of FIG. 4B includes an input and an output. The input of the modulus circuitry 412 is coupled to the output of the interpolation chain circuitry 104 of FIG. 1 and the input of the DPD corrector circuitry 106 of FIGS. 1-3. The output of the modulus circuitry 412 is coupled to the input of the lookup table 414. The output of the lookup table 414 is coupled to the second input of the multiplier circuitry 416.

The multiplier circuitry 410 of FIG. 4B multiplies a DPD estimator coefficient(s) estimated by the DPD estimator (c(i,j)) and a signal statistics value(s) from the signal statistics generator circuitry 304 of FIG. 3. The output product (e.g., c(i,j)*ti)) of the multiplier 410 is applied to the first input of the multiplier circuitry 416, as further described below.

The modulus circuitry 412 of FIG. 4B obtains the input signal x(n) and performs a modulus operation (e.g., an absolute value operation) on the input signal x(n). The modulus circuitry 412 outputs the output signal (e.g., |x(n)|) to the lookup table 414. The lookup table 414 is a basis function lookup table that applies a basis function to the modulated input signal. The basis function corresponds to a basis polynomial, such as a Zernike polynomial. The lookup table 414 outputs the output product (e.g., BFj(|x(n)|) to the second input of the second multiplier circuitry 416.

The multiplier circuitry 416 of FIG. 4B multiplies the output of the multiplier circuitry 410 (e.g., c(i,j)*ti)) to the output of the lookup table 414 (e.g., BFj(|x(n)|)). The output of the multiplier circuitry 416 outputs the output product (e.g., c(i,j)*ti*BFj(|x(n)|), referred to as the envelope term) to the first input of the multiplier circuitry 418. The multiplier circuitry 418 multiplies the output of the multiplier circuitry 416 (e.g., c(i,j)*ti*BFj(|x(n)|)) by the input signal (e.g., x(n)). The multiplier circuitry 418 outputs the output value (e.g., c(i,j)*ti*BFj(|x(n)|)x(n)) to the example summation circuitry 408 of FIG. 4A. Thus, all of the dynamic DPD terms are summed to correspond to the above-Equation 2.

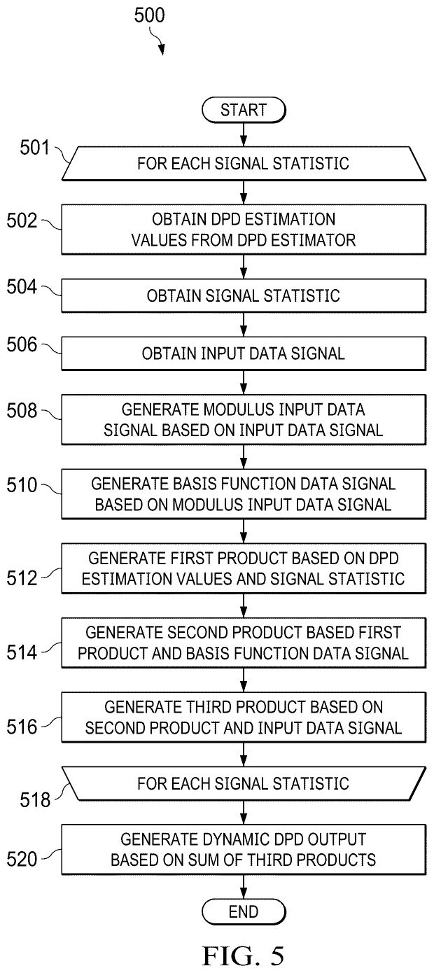

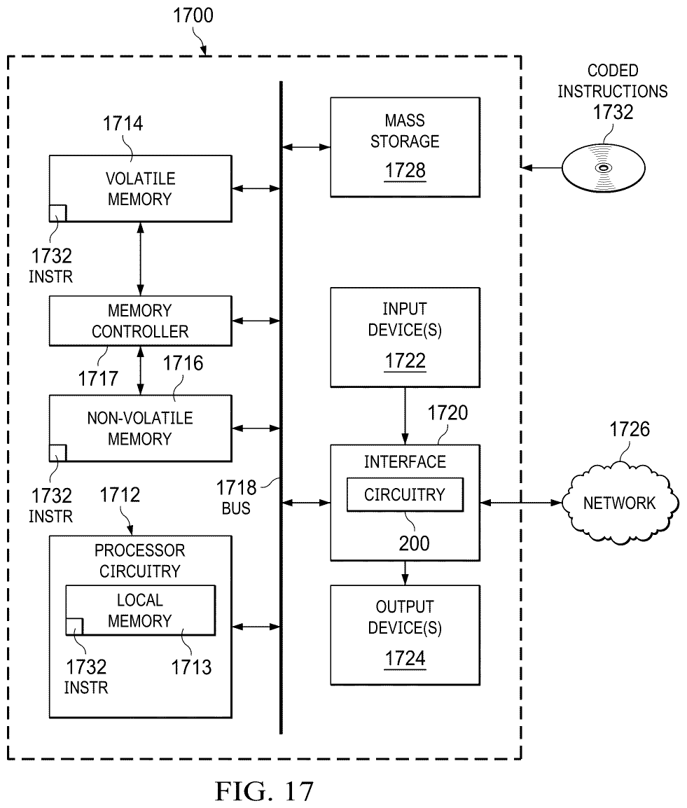

FIG. 5 is a flowchart representative of example machine readable instructions or example operations 500 that may be executed, instantiated, or performed by programmable circuitry to generate a dynamic DPD output value that mitigates the nonlinearity of the PA 116 of FIG. 1. The example machine readable instructions or example operations 500 may be implemented by the DPD corrector circuitry 108 of FIGS. 4A-4B or by the programmable circuitry platform 1700 of FIG. 17. The example machine-readable instructions or the example operations 500 of FIG. 5 begin, for each signal statistics from the signal statistics generator circuitry 304 (blocks 501-518), at block 502, at which the multiplier circuitry 410 obtains the DPD estimation value(s) (c(i,j)) from the DPD estimator circuitry 132.

At block 504, the multiplier circuitry 410 obtains the signal statistic(s) (ti). At block 506, the modulus circuitry 412 and the multiplier circuitry 418 obtain the input data signal (x(n)) from the interpolation chain circuitry 104. At block 508, the modulus circuitry 412 generates a modulus input data signal (e.g., |x(n)|) based on the input data signal. For example, the modulus circuitry 412 generates the modulus input data signal by taking the absolute value of the input data signal. At block 510, the lookup table 414 generates a basis function data signal based on the modulus input data signal. For example, the modulus input data signal is input into the lookup table 414 and the lookup table outputs a basis function of the modulus input data signal.

At block 512, the multiplier circuitry 410 generates a first product based on the DPD estimation coefficient(s) (c(i,j)) and the signal statistic(s) (ti). For example, the multiplier circuitry 410 multiplies the DPD estimation value(s) to the signal statistic(s) (ti). At block 514, the multiplier circuitry 416 generates a second product based on the first product from the output of the multiplier circuitry 410 and the basis function data signal from the output of the lookup table 414. For example, the multiplier circuitry 416 multiplies the first product with the basis function data signal to generate the second product. At block 516, the multiplier circuitry 418 generates a third product based on the second product from the multiplier circuitry 416 and the input data signal (x(n)). For example, the multiplier circuitry 418 multiplies the third product with the input data signal. After each signal statistic has been processed, at block 520, the summation circuitry 408 generates a dynamic DPD output based on the sum of the third products of each of the dynamic DPD term generator circuitry(ies) 402, 404,406. As described above, the dynamic DPD output is summed with the DPD output of the DPD corrector circuitry 106 to generate an output signal that is pre distorted to reduce or eliminate the nonlinearity generated by the PA 116 of FIG. 1.

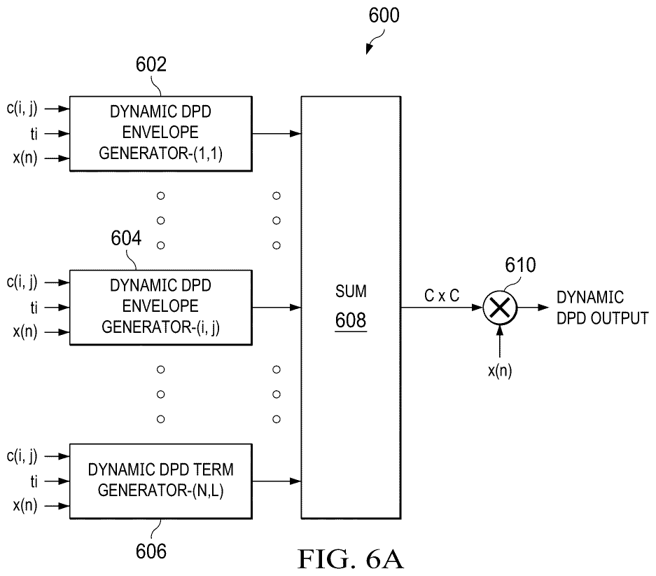

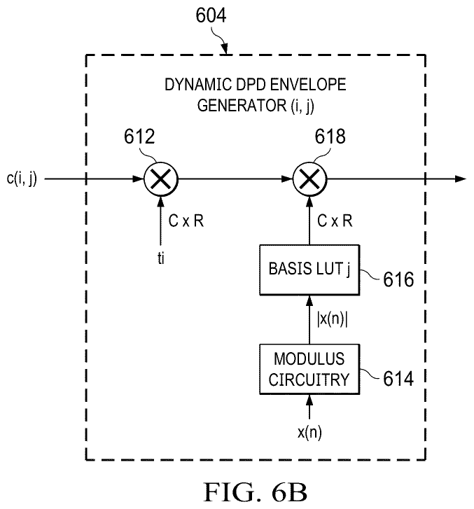

FIG. 6A is a block diagram 600 that corresponds to an alternative implementation of the term generator circuitry 302 of FIG. 3. The example block diagram 600 of FIG. 6A includes example dynamic DPD envelope generator circuitries 602, 604, 606 and example summation circuitry 608, and example multiplier circuitry 610.

The dynamic DPD envelope generator circuitries 602, 604, 606 of FIG. 6A adjust an input signal to generate dynamic DPD envelope terms (e.g., also referred to as weighted envelope terms). For example, the dynamic DPD envelope generators circuitries 602, 604, 606 generate the (i,j)th dynamic DPD envelope terms c(i, j)tᵢBFⱼ(|x(n)|), which are summed by the summation circuitry 608 to generate a weighted DPD envelope term. The multiplier circuitry 610 multiplies the weighted DPD envelope term to the input signal x(n) to generate the dynamic DPD output (e.g., y(n) of the above Equation 2). An example of one of the dynamic DPD envelope generator circuitries 602, 604, 606 is further described below in conjunction with FIG. 6B.

FIG. 6B is an example circuit implementation of the dynamic DPD envelope generator circuitry 604 of FIG. 6A. However, the circuit implementation of FIG. 6B could implement any of the dynamic DPD envelope generator circuitries 602, 604, 606. The DPD envelope generator circuitry 604 includes example multiplier circuitry 612, 618, example modulus circuitry 614, and an example lookup table 616.

The multiplier circuitries 612, 618 of FIG. 6B each include two inputs and an output. The first input of the multiplier circuitry 612 is coupled to the DPD estimator circuitry 132 of FIG. 1. The second input of the multiplier circuitry 612 is coupled to signal statistics generator circuitry 304 of FIG. 3. The output of the multiplier circuitry 612 is coupled to the first input of the multiplier circuitry 618. The second input of the multiplier circuitry 618 is coupled to the output of the lookup table 616. The output of the multiplier circuitry 618 is coupled to the summation circuitry 608.

The modulus circuitry 614 of FIG. 6B includes an input and an output. The input of the modulus circuitry 614 is coupled to the output of the interpolation chain circuitry 104 of FIG. 1 and the input of the DPD corrector circuitry 106 of FIGS. 1-3. The output of the modulus circuitry 614 is coupled to the input of the lookup table 616. The output of the lookup table 616 is coupled to the second input of the multiplier circuitry 618.

The multiplier circuitry 612 of FIG. 6B multiplies a DPD estimator coefficient(s) from the DPD estimator (c(i,j)) and a signal statistics value(s) from the signal statistics generator circuitry 304 of FIG. 3. The output product (e.g., c(i,j)*ti)) of the multiplier circuitry 612 is applied to the first input of the multiplier circuitry 618, as further described below.

The modulus circuitry 614 of FIG. 6B obtains the input signal x(n) and performs a modulus operation (e.g., an absolute value operation) on the input signal x(n). The modulus circuitry 614 outputs the output signal (e.g., |x(n)|) to the lookup table 616. The lookup table 616 is a basis lookup table that applies a basis function to the modulated input signal. The basis function corresponds to a basis polynomial, such as a Zernike polynomial. The lookup table 616 outputs the output product (e.g., BFj(|x(n)|) to the second input of the second multiplier circuitry 618.

The multiplier circuitry 618 of FIG. 6B multiplies the output of the multiplier circuitry 612 (e.g., c(i,j)*ti)) to the output of the lookup table 616 (e.g., BFj(|x(n)|)). The output of the multiplier circuitry 618 outputs the output product (e.g., c(i,j)*ti*BFj(|x(n)|)) to the first input of the summation circuitry 608 of FIG. 6A. The multiplier circuitry 418 of FIG. 4B is not included in the dynamic DPD envelope generator circuitry 604 of FIG. 6B. Instead, the block diagram 600 includes the multiplier circuitry 610 to multiply the output of the summation circuitry 608 of FIG. 6A to the input signal x(n). Accordingly, the output of the multiplier circuitry 610 corresponds to the above Equation 2; however, instead of utilizing three multiplier circuitries for each dynamic DPD envelope generator circuitry 602, 604, 606, only two multipliers for each dynamic DPD envelope generator circuitry 602, 604, 606 and the single multiplier circuitry 610 is needed to generate an output that corresponds to the above Equation 2. Thus, the block diagram 600 utilizes less components than the block diagram 400 of FIG. 4A.

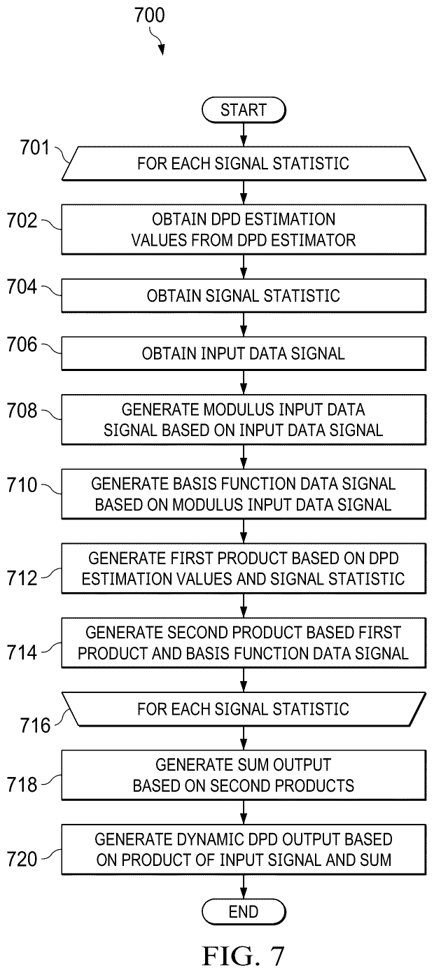

FIG. 7 is a flowchart representative of example machine readable instructions or example operations 700 that may be executed, instantiated, or performed by programmable circuitry to generate a dynamic DPD output value that mitigates the nonlinearity of the PA 116 of FIG. 1. The example machine readable instructions or example operations 700 may be implemented by the DPD corrector circuitry 108 of FIGS. 6A-6B or by the programmable circuitry platform 1700 of FIG. 17. The example machine-readable instructions or the example operations 700 of FIG. 7 begin, for each signal statistics from the signal statistics generator circuitry 304 (blocks 701-716), at block 702, at which the multiplier circuitry 612 obtains the DPD estimation value(s) (c(i,j)) from the DPD estimator circuitry 132.

At block 704, the multiplier circuitry 612 obtains a signal statistic(s) (ti). At block 706, the modulus circuitry 614 and the multiplier circuitry 618 obtain the input data signal (x(n)) from the Interpolation chain circuitry 104. At block 708, the modulus circuitry 614 generates a modulus input data signal (e.g., |x(n)|) based on the input data signal. For example, the modulus circuitry 614 generates the modulus input data signal by taking the absolute value of the input data signal. At block 710, the lookup table 616 generates a basis function data signal based on modulus input data signal. For example, the modulus input data signal is input into the lookup table 616 and the lookup table outputs a basis function of the modulus input data signal.

At block 712, the multiplier circuitry 612 generates a first product based on the DPD estimation value(s) (c(i,j)) and the signal statistic(s) (ti). For example, the multiplier circuitry 612 multiplies the DPD estimation value(s) to the signal statistic(s) (ti). At block 714, the multiplier circuitry 618 generates a second product based on the first product from the output of the multiplier circuitry 610 and the basis function data signal from the output of the lookup table 616. For example, the multiplier circuitry 618 multiplies the first product with the basis function data signal to generate the second product. After each signal statistic has been processed, at block 718, the summation circuitry 608 generates a sum output based on the sum of the third products of each of the dynamic DPD envelope generator circuitry(ies) 602, 604, 606. At block 720, the multiplier circuitry 610 generates dynamic DPD output based on sum output of the summation circuitry 608 and the input data signal (x(n)). For example, the multiplier circuitry 618 multiplies the sum output with the input data signal. As described above, the dynamic DPD output is summed with the DPD output of the DPD corrector circuitry 106 to generate an output signal that is pre distorted to reduce or eliminate the nonlinearity generated by the PA 116 of FIG. 1.

FIG. 8 is a block diagram 800 that corresponds to an alternative implementation of the DPD corrector circuitry 108 of FIGS. 1-2. The example block diagram 800 of FIG. 8 includes the example signal statistics generator circuitry 304, the signal statistics sub-circuitry 306, and the signal statistics sub-circuitry 308 of FIG. 3. The block diagram 800 further includes example decimation circuitry 802, example slow dynamic term generator circuitry 806, example fast dynamics term generation circuitry 808, and example summation circuitry 810.

The signal statistics generator circuitry 304 of FIG. 8 includes an input, first outputs, and second outputs. The first input of the signal statistics generator circuitry 304 is coupled to the output of the interpolation chain circuitry 104. The first outputs of the signal statistics generator circuitry 304 are coupled to the input of the decimator circuitry 802. The second outputs of the signal statistics generator circuitry 304 is coupled to the input of the fast dynamics term generator circuitry 808. As described above, the signal statistics generator circuitry 304 generates signal statistic values (ti) based on the input signal (x(n)). Also, the signal statistics generator circuitry 304 groups the signal statistics into a first group (e.g., slow signal statistics) and a second group (e.g., fast signal statistics) based on the time constants of the signal statistics. For example, the signal statistics generator circuitry 304 can, if a signal statistic value has a time constant above a threshold, the signal statistics generator circuitry 304 adds the signal statistic value to the first group of signal statistics. If the signal statistic value has a time constant below the threshold, the signal statistics generator circuitry 304 adds the signal statistics value to the second group of signal statistics. The signal statistics generator circuitry 304 outputs the first group of signal statistics (e.g., the slow signal statistics, r1, r2, . . . rs) to the decimator circuitry 802 and outputs the second group of signal statistics (e.g., the fast slow signal statistics, d1, d2, . . . , ds) to the fast dynamics term generator circuitry 808.

The decimation circuitry 802 of FIG. 8 includes first inputs, first outputs, and a second output. The first inputs of the decimation circuitry 802 are coupled to the first outputs of the signal statistics generation circuitry 304. The first outputs of the decimation circuitry 802 are coupled to first inputs of the slow dynamics term generator circuitry 806. The second output of the decimation circuitry 802 is coupled to the slow dynamics term generator circuitry 806. The decimation circuitry 802 filters out one or more of the slow signal statistics generated by the signal statistics generator circuitry 304. As described above, the slow signal statistics are signal statistics with particular time constraints that correspond to smaller change between slow signal statistics. Accordingly, instead of processing all of the slow signal statistics, the decimation circuitry 802 only outputs a portion of the slow signal statistics to the slow dynamics term generator circuitry 806 to generate slow dynamics terms. Because the slow signal statistics do not change as much as the fast signal statistics, the slow dynamics term generator circuitry 806 can generate accurate dynamic terms using only a portion of the slow signal statistics. As further described below, a counter can be used to trigger the modulation circuitry 802 to output the Mth slow signal statistics via a signal (e.g., a pulse) at the second input of the decimation circuitry 802.

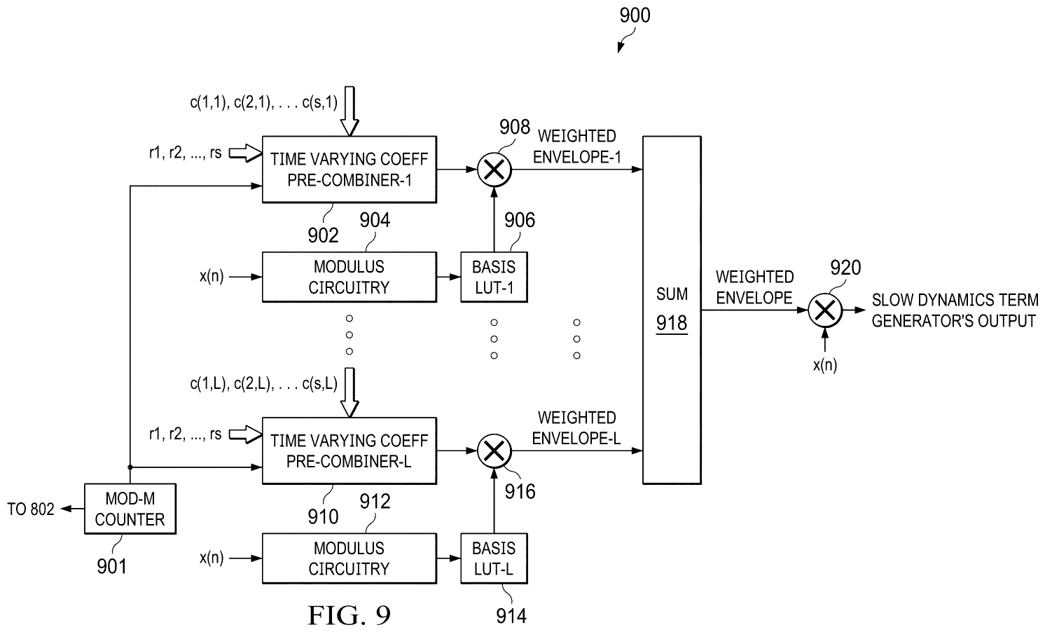

The slow dynamics term generator circuitry 806 of FIG. 8 includes a first input, second inputs, a third input, and a first output. The first input of the slow dynamics term generator circuitry 806 is coupled to the output of the interpolation circuitry 104. The second inputs of the slow dynamics term generator circuitry 806 are coupled to the outputs of the decimation circuitry 802. The third input of the slow dynamics term generator circuitry 806 is coupled to the DPD estimator 132 of FIG. 1. The first output of the slow dynamics term generator circuitry 806 is coupled to a first input of the summation circuitry 810. The slow dynamics term generator circuitry 806 performs a multiplication and accumulation protocol. For example, the slow dynamics term generator circuitry 806 multiplies each slow signal statistic to a particular DPD estimation term from the DPD estimator circuitry 132 and sums the multiple products together. Also, the slow dynamics term generator circuitry 806 multiplies the sum of the multiple products to a basis polynomial that corresponds to the absolute value of an input signal to generate a weighted envelope value. The slow dynamics term generator circuitry 806 adds the weighted envelopes to generate an output weighted envelope. The slow dynamics term generator circuitry 806 outputs a slow dynamic term output based on a product of the output weighted envelope and the input signal. The slow dynamics term generator circuitry 806 is further described below in conjunction with FIG. 9.

The fast dynamics term generator circuitry 808 of FIG. 8 includes a first input, second inputs, a third input, and an output. The first input of the fast dynamics term generator circuitry 808 is coupled to the output of the interpolation circuitry 104. The second inputs of the fast dynamics term generator circuitry 808 are coupled to the outputs of the signal statistics generator circuitry 304. The third input of the fast dynamics term generator circuitry 808 is coupled to the DPD estimator 132 of FIG. 1. The output of the fast dynamics term generator circuitry 808 is coupled to a second input of the summation circuitry 810. The fast dynamics term generator circuitry 808 multiplies the sum of the fast signal statistics to a polynomial that corresponds to the absolute value of an input signal to generate a product. As further described below, the polynomial is included in a lookup table and is a function of the estimated DPD coefficients. The fast dynamics term generator circuitry 808 adds the product to generate an output sum. The fast dynamics term generator circuitry 808 outputs a fast dynamic term output based on a product of the output sum and the input signal. The fast dynamics term generator circuitry 808 is further described below in conjunction with FIG. 9.

The summation circuitry 810 of FIG. 8 includes two inputs and an output. The first input of the summation circuitry 810 is coupled to the output of the slow dynamic term generator circuitry 806. The second input of the summation circuitry 810 is coupled to the output of the fast dynamics term generator circuitry 808. The output of the summation circuitry 810 is coupled to the second input of the summation circuitry 110 of FIG. 1. The summation circuitry 810 adds the output of the slow dynamics term generator circuitry 806 and the output of the fast dynamics term generator circuitry 808.

FIG. 9 is a block diagram 900 that corresponds to an example implementation of the slow dynamic term generator circuitry 806 of FIG. 8. The example block diagram 900 of FIG. 9 includes the example counter circuitry 901, example pre-combiner circuitries 902, 910, example modulus circuitries 904, 912, example lookup tables 906, 914, example multiplier circuitries 908, 916, example summation circuitries 918, and an example multiplier circuitry 920. Although the example block diagram 900 includes multiple modulus circuitries 904, 912, there may be one modulus circuitry 904 with one output that is coupled to the inputs of the multiple lookup tables 906, 914. Also, although there are two pre-combiner circuitries 902, 910, two lookup tables 906, 914, and two multiplier circuitries 908, 916, there may be any number of pre-combiner circuitries, lookup tables, and multiplier circuitries.

The counter circuitry 901 of FIG. 9 includes two outputs. The first output of the counter circuitry 901 is coupled to the decimation circuitry 802 of FIG. 8. The second output of the counter circuitry 901 is coupled to the inputs of the pre-combiner circuitries 902, 910.

The counter circuitry 901 outputs a count from 0 to the M−1, where M is the number of decimations of the decimation circuitry 802 of FIG. 8. As further described below, the pre-combiner circuitries 902, 910 use the count to trigger a multiplication and accumulation protocol. Also, the counter circuitry 901 outputs a pulse after the M count is reached. The decimation circuitry 802 uses the pulse to forward a slow signal statistic and filters out or discard statistics that are not calculated near the pulse. For example, if a slow signal statistic is generated every 100 milliseconds and the pulse occurs every 500 milliseconds, the decimation circuitry 802 discards the first slow signal statistics and forwards the fifth slow signal statistics generated near the 500-millisecond mark.

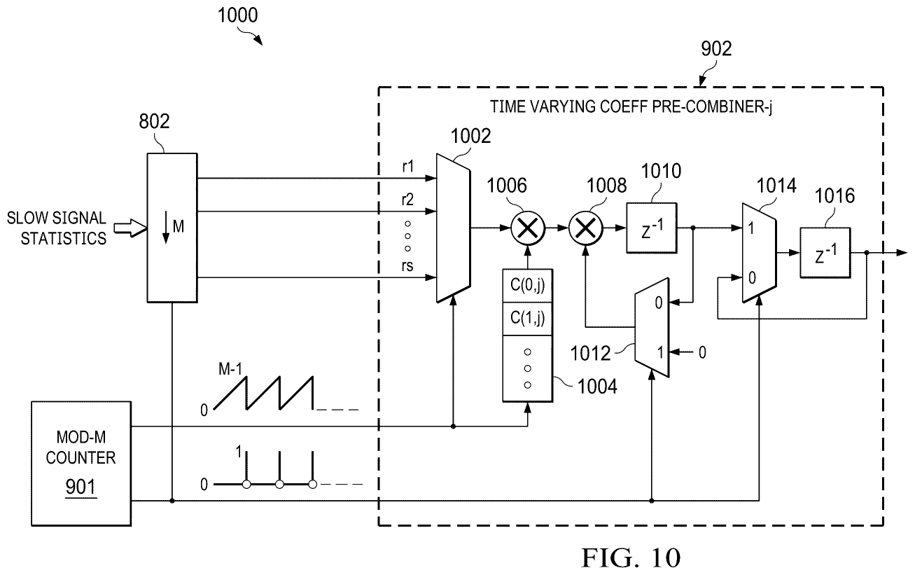

The pre-combiner circuitry 902 of FIG. 9 is time varying coefficient pre-combining circuitry. The pre-combiner circuitry 902 includes a first input, second inputs, third inputs, and an output. The first input of the pre-combiner circuitry 902 is coupled to the output of counter circuitry 901. The second inputs of the pre-combiner circuitry 902 are coupled to the outputs of the decimation circuitry 802. The third inputs of the pre-combiner circuitry 902 are coupled to the outputs of the DPD estimator circuitry 132 of FIG. 1. The output of the pre-combiner circuitry 902 is coupled to a first input of the multiplier circuitry 908. The pre-combiner circuitry 902 performs a multiplication and accumulation of the decimated slow signal statistics and the DPD estimation values from the DPD estimator circuitry 132, as further described below in conjunction with FIG. 10.

The modulus circuitry 904 of FIG. 9 generates an output signal that is an absolute value of the input signal. The modulus circuitry 904 includes an input and an output. The input of the modulus circuitry 904 is coupled to the output of the interpolation chain circuitry 104. The output of the modulus circuitry 904 is coupled to an input of the lookup table 906. The modulus circuitry 904 obtains the input signal x(n) and performs a modulus operation (e.g., an absolute value operation) on the input signal x(n). The modulus circuitry 904 outputs the output signal (e.g., |x(n)|) to the lookup table 906. The lookup table 906 is a basis lookup table that applies a basis function to the modulated input signal. The basis function corresponds to a basis polynomial, such as a Zernike polynomial. The lookup table 906 outputs the output product (e.g., BFj(|x(n)|) to the second input of the multiplier circuitry 908.

The multiplier circuitry 908 of FIG. 9 multiplies the two inputs to generate a weighted envelope value. The multiplier circuitry 908 includes two inputs and an output. The first input of the multiplier circuitry 908 is coupled to the output of the pre-combiner circuitry 902. The second input of the multiplier circuitry 908 is coupled to the output of the lookup table 906.

The multiplier circuitry 908 multiplies the output of the multiplier circuitry 410 (e.g., Σc(i, j)*ri to the output of the lookup table 414 (e.g., BFj(|x(n)|)). The output of the multiplier circuitry 908 outputs the output product (e.g., Σc(i, j)*ri*BFj(|x(n)|)), referred to as the envelope term or the weighted envelope term) to the first input of the summation circuitry 918.

The pre-combiner circuitry 910 of FIG. 9 is time varying coefficient pre-combining circuitry. The pre-combiner circuitry 910 includes a first input, second inputs, third inputs, and an output. The first input of the pre-combiner circuitry 910 is coupled to the output of counter circuitry 901. The second inputs of the pre-combiner circuitry 910 are coupled to the outputs of the decimation circuitry 802. The third inputs of the pre-combiner circuitry 910 are coupled to the outputs of the DPD estimator circuitry 132 of FIG. 1. The output of the pre-combiner circuitry 910 is coupled to a first input of the multiplier circuitry 916. The pre-combiner circuitry 910 performs a multiplication and accumulation of the decimated slow signal statistics and the DPD estimation values from the DPD estimator circuitry 132, as further described below in conjunction with FIG. 10.

The modulus circuitry 912 of FIG. 9 generates an output signal that is an absolute value of the input signal. The modulus circuitry 912 includes an input and an output. The input of the modulus circuitry 912 is coupled to the output of the interpolation chain circuitry 104. The output of the modulus circuitry 912 is coupled to an input of the lookup table 914. The modulus circuitry 912 obtains the input signal x(n) and performs a modulus operation (e.g., an absolute value operation) on the input signal x(n). The modulus circuitry 912 outputs the output signal (e.g., |x(n)|) to the lookup table 914. The lookup table 914 is a basis lookup table that applies a basis function to the modulated input signal. The basis function corresponds to a basis polynomial, such as a Zernike polynomial. The lookup table 914 outputs the output product (e.g., BFj(|x(n)|)) to the second input of the multiplier circuitry 916.

The multiplier circuitry 916 of FIG. 9 multiplies the two inputs to generate a weighted envelope value. The multiplier circuitry 916 includes two inputs and an output. The first input of the multiplier circuitry 916 is coupled to the output of the pre-combiner circuitry 910. The second input of the multiplier circuitry 916 is coupled to the output of the lookup table 914. The multiplier circuitry 916 multiplies the output of the multiplier circuitry 410 (e.g., c(i,j)*ri)) to the output of the lookup table 414 (e.g., a linear combination of the basis function times the DPD coefficients). The output of the multiplier circuitry 916 outputs the output product (e.g., Σc(i, j)*ri*BFj(|x(n)|)), referred to as the envelope term or the weighted envelope term) to the Lth input of the summation circuitry 918.

The summation circuitry 918 of FIG. 9 sums the weighted envelopes output by the multiplier circuitries 908, 916. The summation circuitry 918 includes L inputs for the L weighted envelopes generated by the L multiplier circuitries 908, 916, etc., and one output. The first input of the summation circuitry 918 is coupled to the output of the multiplier circuitry 908 and the Lth input of the summation circuitry 918 is coupled to the output of the Lth multiplier circuitry 916. The output of the summation circuitry 918 is coupled to the first input of the multiplier circuitry 920.

The multiplier circuitry 920 of FIG. 9 generates an output product based on sum of the weighted envelopes and the input signal, x(n). The multiplier circuitry 920 includes two inputs and an output. The first input of the multiplier circuitry 920 is coupled to the output of the summation circuitry 918. The second input of the multiplier circuitry 920 is coupled to the output of the interpolation circuitry 104. The multiplier 920 generates the slow dynamic output term based on a product of the weighted envelope term and the input signal.

FIG. 10 is an example circuit implementation of the pre-combiner circuitry 902, 910 of FIG. 9. FIG. 9 includes the decimation circuitry 802 of FIG. 8 and the counter circuitry 901 of FIG. 9. The pre-combiner circuitry 902 includes example multiplexers 1002, 1012, 1014, an example lookup table 1004, example multiplier circuitry 1006, example summation circuitry 1008, example registers 1010, 1016.

In the example of FIG. 10, if the decimation circuitry 802 uses a decimation factor of M (e.g., only forwarding every Mth sample of the input signal). If the number of decimated slow signal statistics obtained by the decimation circuitry 802 is less than or equal to the decimation factor M, a single multiple and accumulate unit can be used for every basis function lookup table. If the number decimated slow signal statistics is greater than the decimation factor of M, the decimated signal statistics and coefficients are split into sub-groups of M and separate multiply and accumulation logic is run for each sub-group in parallel.

The multiplexer circuitry 1002 of FIG. 10 outputs one of the inputs based on a value at a select input. The multiplexer circuitry 1002 includes s inputs, a select input, and an output. The s inputs of the multiplexer circuitry 1002 are coupled to the outputs of the decimation circuitry 802. The select input of the multiplexer circuitry 1002 is coupled to the output of the counter circuitry 901. The output of the multiplexer circuitry 1002 is coupled to a first input of the multiplier circuitry 1006. The multiplexer circuitry 1002 obtains the count from the counter circuitry 901 at the select input. Accordingly, multiplexer circuitry 1002 outputs one of the decimated slow signal statistics at the output terminal of the multiplexer circuitry 1002 based on the count output by the counter circuitry 901.

The lookup table 1004 stores the DPD estimator coefficients of the DPD estimator circuitry 132 of FIG. 1. The lookup table 1004 includes an input and an output. The input of the lookup table 1004 is coupled to the counter circuitry 901. The output of the lookup table 1004 is coupled to the second input of the multiplier circuitry 1006. The lookup table 1004 stores the DPD estimator values and outputs one of the DPD coefficients based on the count output by the counter circuitry 901. In this manner, a particular decimated slow signal statistic is output to the multiplier circuitry 1006 at the same time as a particular DPD estimation value is output to the multiplier circuitry 1006.

The multiplier circuitry 1006 of FIG. 10 generates a product based on two input signals. The multiplier circuitry 1006 includes two input signals and an output signal. The first input of the multiplier circuitry 1006 is coupled to the output of the multiplexer circuitry 1002. The second input of the multiplier circuitry 1006 is coupled to the output of the lookup table 1004. The multiplier circuitry 1006 multiplies the output of the multiplexer circuitry 1002 to the output of the lookup table 1004 to generate a product based on a particular decimated slow signal statistics with a DPD estimation value. The multiplier circuitry 1006 outputs the product to the example summation circuitry 1008.

The summation circuitry 1008 of FIG. 10 generates a sum based on two input values. The summation circuitry 1008 includes two inputs and an output. The first input of the summation circuitry 1008 is coupled to the output of the multiplier circuitry 1006. The second input of the summation circuitry 1008 is coupled to the output of the multiplexer circuitry 1012. As further described below, the multiplexer circuitry 1012 outputs an accumulated sum of the products generated by the multiplier circuitry 1006. Accordingly, the summation circuitry 1008 sums the product generated by the current product of the multiplier circuitry 1006 to previous generated products of the multiplier circuitry 1006.

The register 1010 of FIG. 10 stores a value. The register 1010 includes an input and an output. The input of the register 1010 is coupled to the output of the summation circuitry 1008. The output of the register 1010 is coupled to the first input of the multiplexer circuitry 1012 and the first input of the multiplexer circuitry 1014. The register 1010 stores and holds the value output by the summation circuitry 1008 until a new value from the summation circuitry 1008 is output to the register 1010. The register 1010 outputs the held value to the first inputs of the multiplexers 1012, 1014.

The multiplexer 1012 of FIG. 10 outputs one of the input values based on the value at a select input. The multiplexer 1012 includes two inputs, a select input, and an output. The first input of the multiplexer 1012 is coupled to the output of the register 1010. The second input of the multiplexer 1012 is coupled to a common terminal (e.g., ground). The select input is coupled to the counter circuitry 901. The output of the multiplexer 1012 is coupled to a second input of the summation circuitry 1008. The multiplexer 1012, if the output of the counter circuitry 901 is zero, outputs the accumulated sum from the register 1010, which is added to a subsequent product via the summation circuitry 1008. Accordingly, the summation circuitry 1008, the register 1010, and the multiplexer circuitry 1012 accumulates the products generate by the multiplier circuitry 1006. After the M values are multiplied and accumulated, the counter circuitry 901 outputs a pulse to cause the multiplexer circuitry 1012 to output a low voltage to reset the register 1010 for a new set of M slow signal statistics.

The multiplexer 1014 of FIG. 10 outputs one of the input values based on the value at a select input. The multiplexer 1014 includes two inputs, a select input, and an output. The first input of the multiplexer 1014 is coupled to the output of the register 1010. The second input of the multiplexer 1014 is coupled to an output of the register 1016. The select input is coupled to the counter circuitry 901. The output of the multiplexer 1014 is coupled to an input of the register 1016. The multiplexer 1014, if the output of the counter circuitry 901 is zero, outputs the accumulated sum from the register 1010, which is stored in the register 1016. If the output of the counter circuitry 901 pulses high and the register 1010 is being reset, the multiplexer 1014 outputs the accumulated sum from the output of the register 1016. Accordingly, the register 1016 maintains the accumulated sum while the register 1010 is reset for the subsequent multiplications.

The register 1016 of FIG. 10 stores a value. The register 1016 includes an input and an output. The input of the register 1016 is coupled to the output of the multiplexer 1014. The output of the register 1016 is coupled to the first input of the multiplier 908. The register 1016 stores and holds the accumulated products generated by the multiplier circuitry 1006 and outputs the accumulated product value to the multiplier 908 of FIG. 9.

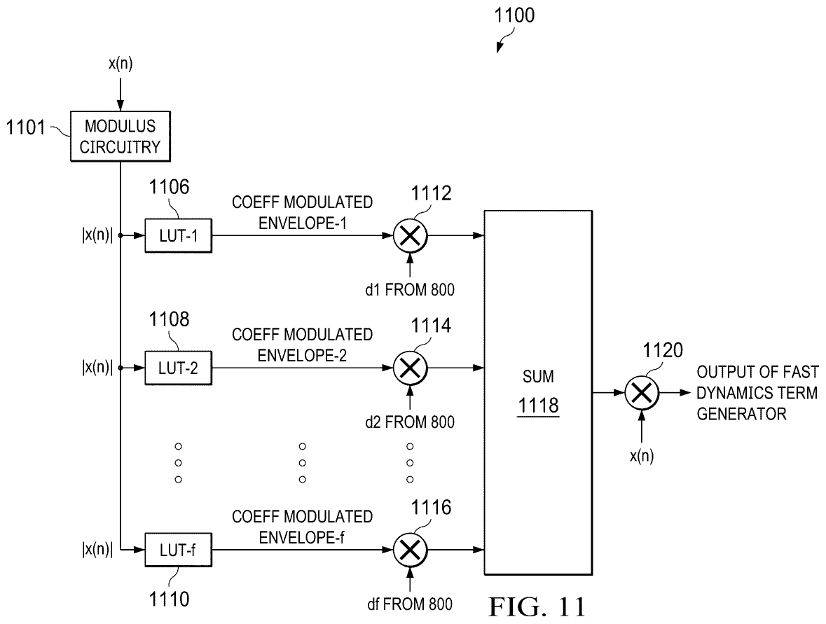

FIG. 11 is a block diagram 1100 of an example implementation of the fast dynamic term generator circuitry 808 of FIG. 8. The block diagram 1100 of FIG. 11 includes example modulus circuitry 1101, example lookup tables 1106, 1108, 1110, example multiplier circuitry 1112, 1114, 1116, example summation circuitry 1118, and example multiplier circuitry 1120. Although the block diagram 110 includes three lookup tables and three multiplier circuitries for three fast signal statistics, there may be any number of lookup tables and multiplier circuitries for any number of signal statistics.

The modulus circuitry 1101 of FIG. 11 includes an input and an output. The input of the modulus circuitry 1101 is coupled to the output of the interpolation chain circuitry 104 of FIG. 1 and the input of the DPD corrector circuitry 106 of FIGS. 1-3. The output of the modulus circuitry 1101 is coupled to the inputs of the lookup tables 1106, 1108, 1110. The modulus circuitry 1101 generates an output signal that is the absolute value of the input signal. The outputs of the lookup tables 1106, 1108, 1110 are coupled to the respective first inputs of the multiplier circuitries 1112, 1114, 1116.

The multiplier circuitries 1112, 1114, 1116 of FIG. 11 each include two inputs and an output. The first inputs of the multiplier circuitries 1112, 1114, 1116 are coupled to respective outputs of the lookup tables 1106, 1108, 1110. The second inputs of the multiplier circuitries 1112, 1114, 1116 are coupled to respective outputs of the signal statistics generator circuitry 304 of FIG. 3. The corresponding outputs of the multiplier circuitries 1112, 1114, 1116 are coupled to the respective inputs of the summation circuitry 1118. The output of the summation circuitry 1118 is coupled to the first input of the multiplier circuitry 1120. The multiplier circuitry 1120 includes two inputs and an output. The first input of the multiplier circuitry 1120 is coupled to the output of the summation circuitry 1118. The second input of the multiplier circuitry 1120 is coupled to the output of the interpolation chain circuitry 104. The output of the multiplier circuitry 1120 is coupled to the input of the summation circuitry 810 of FIG. 8.

The modulus circuitry 1101 of FIG. 11 obtains the input signal x(n) and performs a modulus operation (e.g., an absolute value operation) on the input signal x(n). The modulus circuitry 1101 outputs the output signal (e.g., |x(n)|) to the lookup tables 1106, 1108, 1110. The lookup tables 1106, 1108, 1110 is a basis lookup table that applies a basis function to the modulated input signal. The contents of the respective lookup tables 1106, 1108, 1110 include a sum of the DPD estimated coefficients times the basis function LUT output. Accordingly, the content of each LUT depends on the DPD estimated coefficients (e.g., c(i,j)). The basis function corresponds to a basis polynomial, such as a Zernike polynomial. The lookup tables 1106, 1108, 1110 outputs the respective output products (e.g., BFj(|x(n)|) to the first inputs of the corresponding multiplier circuitries 1112, 1114, 1116.

The multiplier circuitry 1112 of FIG. 11 multiplies the output of the lookup table 1106 (e.g., BFj(|x(n)|)) and a fast signal statistics value (d1) from the signal statistics generator circuitry 304 of FIG. 3. The output product (e.g., BFj(|x(n)|*d1)) of the multiplier circuitry 612 is applied to the summation circuitry 1118. The summation circuitry 1118 sums the output values from the multiplier circuitries 1112, 1114, 1116. The summation circuitry 1118 outputs the sum to the multiplier circuitry 1120. The multiplier circuitry 1120 multiplies the sum to the input signal (x(n)) to generate a fast dynamics term output that is provided to the example summation circuitry 810 of FIG. 8.

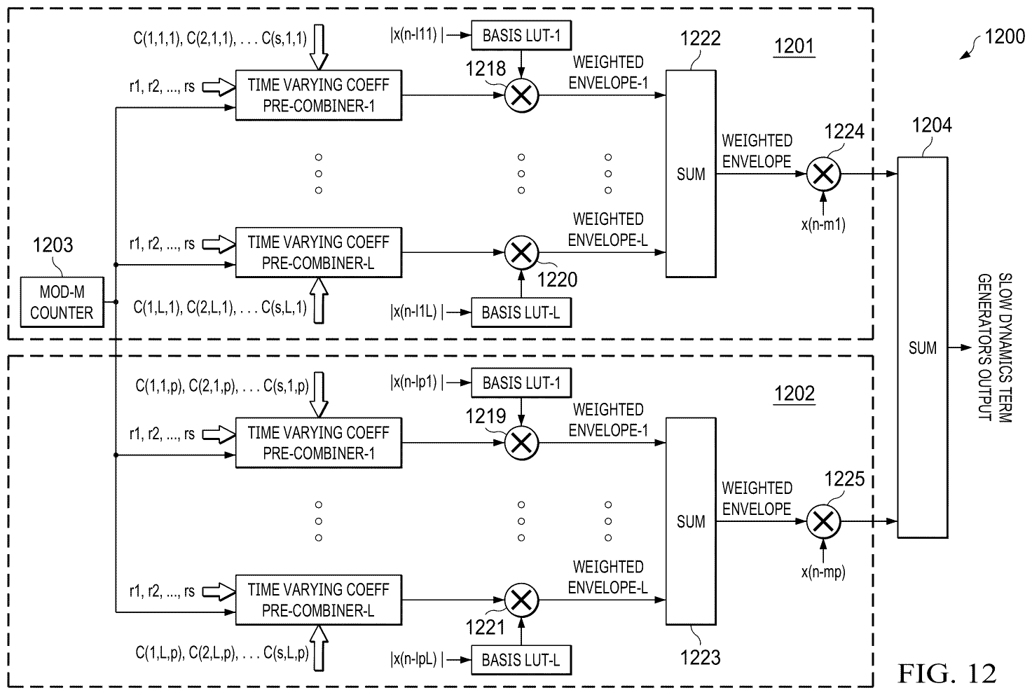

FIG. 12 is a block diagram 1200 that corresponds to an example implementation of the slow dynamic term generator circuitry 806 of FIG. 8 that accounts for lag in DPD terms. The example block diagram 1200 of FIG. 12 includes first slow dynamic term generation sub-circuitry 1201 and second slow dynamic term generation sub-circuitry 1202, an example counter 1203, and example summation circuitry 1204. However, the block diagram 1200 may include any number of slow dynamic term generation circuitries.

The example first and second slow dynamic term generation sub-circuitry 1201, 1202 of FIG. 12 operate in a similar manner as the slow dynamics term generation circuitry 900 of FIG. 9. For example, each component of the slow dynamic term generation sub-circuitry 1201, 1202 operates as described above in conjunction with FIG. 9. However, a lagged input signal is applied to the modulus circuitries (not shown) and the lagged input signal applied to the multiplication circuitries 1218, 1220 corresponds to a previous input signal. For example, the lagged input signal of a first modulus circuitry is a first previous input signal (e.g., x(n−l11)), the lagged input signal of a second modulus circuitry is a Lth previous input signal (e.g., x(n−l1L)), the lagged input signal of a third modulus circuitry is a lagged input signal (e.g., x(n−lp1)), and the lagged input signal of a fourth modulus circuitry is a lagged previous input signal (e.g., x(n−lpL)), where s, L, and p correspond to the amount of lagged terms and/or DPD coefficients. The previous input signals may be stored in memory, a latch and hold circuit, a buffer, or any other storage unit. Also, the input signal of the multiplier circuitry 1218 is a first previous input signal (e.g., x(n−m1)) and the input signal of the multiplier circuitry 1218 is a second previous input signal (e.g., x(n−m1)), where m1 corresponds to the amount of lag in the term (e.g., m1=1 means x(n−1) is used, m1=−1 means x(n+1) is used).

As described above, the dynamic DPD terms could have lags on the envelope and the DPD input. In the example of FIG. 12, the summation circuitry 1222, 1223 of the respective slow dynamic term generation sub-circuitries 1201, 1202 sums the weighted envelopes corresponding to the same DPD input lag before the respective multiplier circuitry 1224, 1225 multiplies with the DPD input delayed by the corresponding lag. The summation circuitry 1204 generates the output slow dynamic term by adding the output products from the multiplication circuitries 1218, 1220. In this manner, the slow dynamic terms for each input lag are generated and then is added to generate an overall slow dynamic term output. In some examples, the summation circuitry 1204 can obtain an output from the multiplier circuitry 920 of FIG. 9 so that the output slow dynamics term considers the current input signal and previous or subsequent input signals (e.g., lagged input signal).

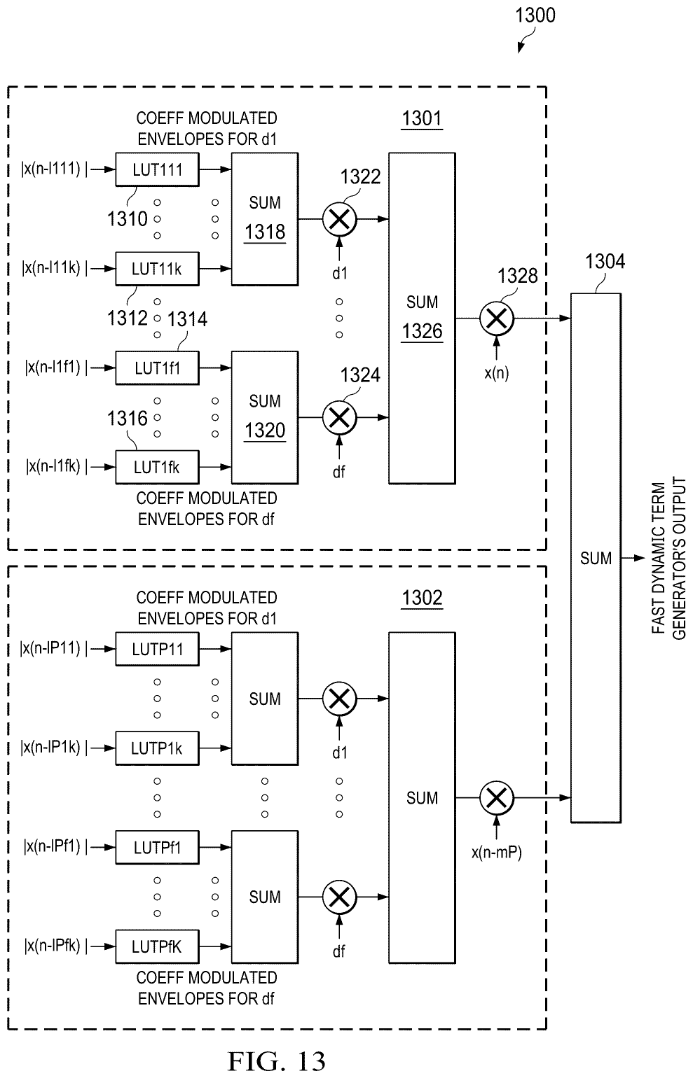

FIG. 13 is a block diagram 1300 that corresponds to an example implementation of the fast dynamic term generator circuitry 808 of FIG. 8 that accounts for lag in DPD terms. The example block diagram 1300 of FIG. 13 includes first fast dynamic term generation sub-circuitry 1301, second fast dynamic term generation sub-circuitry 1302, and example summation circuitry 1304. The first fast dynamics term generation circuitry 1301 includes modulus circuitry (not shown), lookup tables 1310, 1312, 1314, 1316, summation circuitries 1318, 1320, multiplier circuitries 1322, 1324, 1328, and summation circuitry 1236. However, the block diagram 1300 may include any number of fast dynamic term generation circuitries for any number of lagged DPD signals.

The lookup tables 1310, 1312, 1314, 1316 of FIG. 13 each include an input and an output. The input of the lookup tables 1310, 1312, 1314, 1316 are coupled to modulus circuitry (not shown) that obtains previous input signals (e.g., x(n−l111), . . . , x(n−l11K), x(n−1f1), . . . x(n−1fK)). The respective outputs of the lookup tables 1310, 1312, 1314, 1316 are coupled to corresponding summation circuitries 1318, 1320. The lookup tables 1310, 1312, 1314, 1316 operate in a substantially similar manner as the lookup tables 1106, 1108, 1110 of FIG. 11.

The summation circuitries 1318, 1120 of FIG. 13 each include inputs and an output, the inputs of the summation circuitries 1318, 1120 are coupled to the corresponding lookup tables 1310, 1312, 1314, 1316. The outputs of the summation circuitries are coupled to the corresponding multiplier circuitries 1322, 1324. The multiplier circuitries 1322, 1324 each include two inputs and an output. The first input of the multiplier circuitry 1322 is coupled to the output of the summation circuitry 1226, the second input of the multiplier circuitry 1322 is coupled to the signal statistics generation circuitry 304 of FIG. 3 or 8, and the output of the multiplier circuitry 1322 is coupled to the first input of the summation circuitry 1326. The first input of the multiplier circuitry 1324 is coupled to the output of the summation circuitry 1320, the second input of the multiplier circuitry 1324 is coupled to the signal statistics generation circuitry 304 of FIG. 3 or 8, and the output of the multiplier circuitry 1324 is coupled to the first input of the summation circuitry 1326.

The summation circuitry 1326 of FIG. 13 includes two inputs and an output. The first input of the summation circuitry 1326 is coupled to the output of the multiplier circuitry 1322. The second input of the summation circuitry 1326 is coupled to the output of the multiplier circuitry 1324. The output of the summation circuitry 1326 is coupled to the first input of the multiplier circuitry 1328. The multiplier circuitry 1328 includes two inputs and an output. The first input of the multiplier circuitry 1328 is coupled to the output of the summation circuitry 1326 and the second input of the multiplier circuitry 1328 is coupled to a storage device that stores a lagged input signal, and the output of the multiplier circuitry 1328 is coupled to an input of the summation circuitry 1304.

In the example of FIG. 13, the example first and second fast dynamics term generation circuitry 1301, 1302 operate in a similar manner as the fast dynamics term generation circuitry 1100 of FIG. 11. However, the input signal applied to the modulus circuitries and the input signal applied to the multiplication circuitries 1218, 1220 corresponds to a previous or future input signal. Also, the summation circuitry 1318 sums outputs of corresponding lookup tables 1310, 1312, 1314, 1316 before the multiplier circuitry 1322 multiplies with the df fast signal statistics. Also, the second fast dynamics term generation circuitry 1302 operates in the same manner as the first fast dynamics term generation circuitry 1301 with different previous input signals. Accordingly, the block diagram 1300 of FIG. 13 produces fast dynamic terms for each input lag and adds them to generate an overall output fast dynamics term. In some examples, the summation circuitries 1304 can obtain an output from the multiplier circuitry 1120 of FIG. 11 so that the output fast dynamics term considers the current input signal and previous input signals (e.g., lagged input signal).

FIG. 14 illustrates an example block diagram 1400 including the first signal statistics sub-circuitry 306 of FIG. 3. The example block diagram 1400 includes mapping function circuitry 1402, example decimation logic circuitries 1404, 1406, 1408, example decimation circuitries 1410, 1412, 1414, and statistics generator circuitries 1416, 1418, 1420.

The mapping function circuitry 1402 of FIG. 14 (also referred to as signal mapper circuitry or modulus circuitry) has an input coupled to the output of the interpolation chain circuitry 104 and an output coupled to the inputs of the decimation logic circuitries 1404, 1406, 1408. The respective outputs of the decimation logic circuitries 1404, 1406, 1408 are coupled to the inputs of the corresponding decimation circuitries 1410, 1412, 1414. The outputs of the respective decimation circuitries 1410, 1412, 1414 are coupled to the inputs of the corresponding statistics generator circuitries 1416, 1418, 1420. The outputs of the statistics generators 1416, 1418, 1420 are coupled to the second signal statistics sub-circuitry 308 and the term generator circuitry 302.

In some examples, the mapping function circuitry 1402 is configured to provide the absolute value of the signal x(n) at the output of the mapping function circuitry 1402. The provided signal is received at the inputs of the decimation logic circuitries 1404, 1406, 1408.

The decimation logic circuitries 1404, 1406, 1408 select and apply a decimation function to cause the decimation circuitry 1410 to decimate the absolute value of the input signal x(n). For example, the decimation logic circuitries 1404, 1406, 1408 may maintain a moving average of the absolute value of the input signal (e.g., |x(n)|) over time, a weighted moving average of the absolute value of the input signal over time (e.g., where the weights are based on the time constants of the signal statistics), a running maximum of the input signal over time, a running minimum of the absolute value of the input signal over time, or any other statistical analysis of the absolute value of the input signal over time. In this manner, instead of determining signal outputting the entire absolute value of the input signal to the signal statistics generator circuitries 1416, 1418, 1420, the decimation logic circuitries 1404, 1406, 1408 and the corresponding decimation circuitries 1410, 1412, 1414, determine a value representative of the absolute value of the input signal and lower the rate at the input of the statistics generation circuitries 1416, 1418, 1420. Because typical DPD rates (e.g., 100 MHz) are high and for such DPD rate, signal statistics have large enough tie constant where there is no significant change for 10-20 samples, the value representative of the absolute value of the input signal is a sufficient representation that results in power reduction for the statistics generation circuitries 1416, 1418, 1420. Also, decimating the absolute value of the input signal closes the timing for signal statistics derived from state dependent dual time constant filter included in the statistics generation circuitries 1416, 1418, 1420, as further described below. In some examples, the decimation logic circuitries 1404, 1406, 1408 can be combined into one decimation function circuit and the decimation circuitries 1410, 1412, 1414 can be combined into on decimation function, where the output of the single decimation function is coupled to the inputs of the multiple statistics generator circuitries 1416, 1418, . . . , 1420.

As shown, the signal statistics sub-circuitry 306 includes q number of statistics generator circuitries 1416, 1418, . . . , 1420. Each statistics generator is configured to provide one of the signal statistics u₁, u₂, . . . , u_{q} respectively. In some examples, the signal statistics are generated according to the equation uᵢ(n)=ƒᵢ({|x′(n)|, |x′(n−1)|, . . . , |x′(0)|}), where i=1, 2, . . . , q, and x′(n) is the nth sample of decimated x(n) (e.g., at the time instance n). In the example of FIG. 14, the function ƒᵢ corresponds to the ith statistics generator. For example, the function ƒ₁ corresponds to the statistics generator 1416, the function ƒ₂ corresponds to the statistics generator 1418, the function ƒ_{q} corresponds to the statistics generator circuitry 1420, etc.

In some examples, each statistics generator circuitry generates an average of the input of the statistics generator circuitry, and provides the generated average at the output of the statistics generator circuitry. For example, the statistics generator circuitry includes a state dependent dual time constant filter. An example state dependent dual time constant filter can be modeled by the below-Equations 3 and 4.

$$\begin{matrix}( 1 + 2 {f}_{DPD} {τ}_{d} ) out ( n ) + ( 1 - 2 {f}_{DPD} {τ}_{d} ) out ( n - 1 ) = 2 \vert in ( n ) \vert , out ( n - 1 ) > \vert in ( n ) \vert & ( Equation 3 ) \\ ( 1 + 2 {f}_{DPD} {τ}_{u} ) out ( n ) + ( 1 - 2 {f}_{DPD} {τ}_{u} ) out ( n - 1 ) = 2 \vert in ( n ) \vert , out ( n - 1 ) \leq \vert in ( n ) \vert & ( Equation 4 )\end{matrix}$$

In the above Equations 3 or 4, in(n) is the input of the filter, out(n) is the output of the filter, and ƒ_{DPD} is the dynamic DPD sampling frequency. Filter parameters τ_{d} and τᵤ denote the discharging and charging time constants respectively, which may be independent (e.g., different values) for each statistics generator. In some examples, the filter parameters τ_{d} and τᵤ vary depending on a type of the PA (e.g., PA 116). In an alternative example, the statistics generator includes a moving average filter with length Lₖ, k=1, 2, . . . , q.

The second signal statistics sub-circuitry 308 is configured to generate the second set of signal statistics based on the first set of signal statistics. For example, the second signal statistics sub-circuitry 308 generates the second set of signal statistics v_{f1}, v₂, . . . , vᵣ according to the below Equation 5.

$${v}_{i} = {u}_{1}^{{n}_{i 1}} * {u}_{2}^{{n}_{i 2}} * ⋯ * {u}_{q}^{{n}_{iq}} \qquad ( Equation 5 )$$

Where nᵢ₁, nᵢ₂, . . . , n_{iq} are non-negative integers. The values of the non-negative integers, for example, vary based on a type of the PA (e.g., PA 116). Furthermore, the number of signal statistics generated by the first signal statistics sub-circuitry 306 may be dependent on the type of the PA. In some examples, the values of p, q, r, n are determined based on the type of the PA.

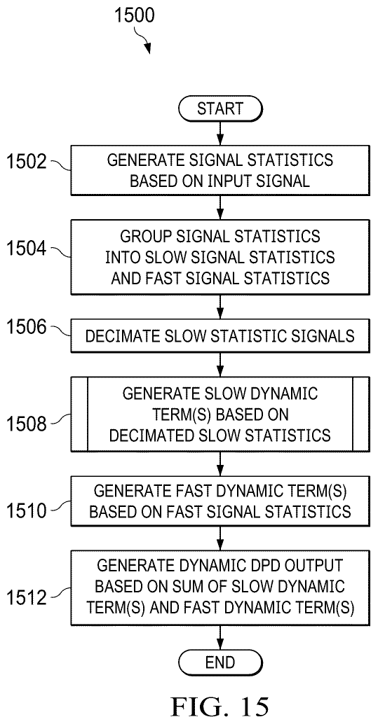

FIG. 15 is a flowchart representative of example machine readable instructions or example operations 1500 that may be executed, instantiated, or performed by programmable circuitry to generate a dynamic DPD output value that mitigates the nonlinearity of the PA 116 of FIG. 1. The example machine readable instructions or example operations 1500 may be implemented by the block diagrams and circuits of FIGS. 1-3 and 8-14 or by the programmable circuitry platform 1700 of FIG. 17. The example machine-readable instructions or the example operations 1500 of FIG. 15 begin, at block 1502, at which the signal statistics generation circuitry 304 of FIGS. 3 and 8 generates signal statistics based on the input data signal.

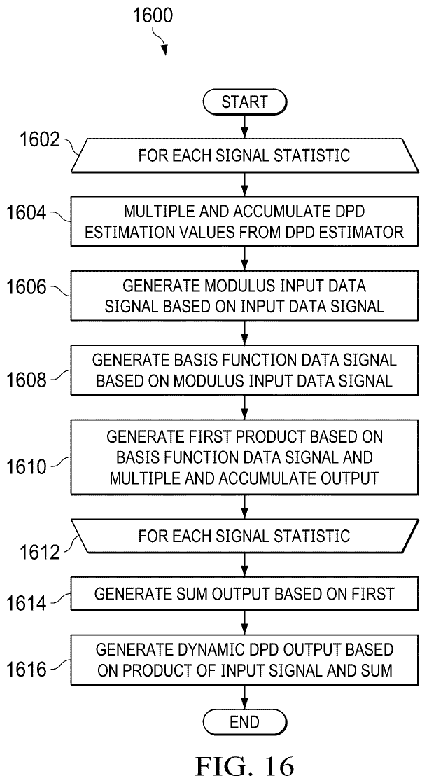

At block 1504, the signal statistics generator circuitry 304 groups the signal statistics into slow signal statistics and fast signal statistics based on the time constant of the generated signal statistics, as further described above in conjunction with FIG. 8. At block 1506, the decimation circuitry 802 of FIG. 8 decimates the slow signal statistics. At block 1508, the slow dynamics term generator circuitry 806 generates an output slow dynamic term based on the decimated slow signal statistics, as further described below in conjunction with FIG. 16. At block 1510, the fast dynamic term generator circuitry 808 generates an output fast dynamic term based on the fast signal statistics, as further described above in conjunction with FIGS. 11 and 13. At block 1512, the summation circuitry 810 generates a dynamic DPD output based on the sum of the slow dynamic term and the fast dynamic term.

FIG. 16 is a flowchart representative of example machine readable instructions or example operations 1508 that may be executed, instantiated, or performed by programmable circuitry to generate an output slow dynamic term based on decimated slow signal statistics. The example machine readable instructions or example operations 1508 may be implemented by the slow dynamics term generator circuitry 806 of FIGS. 8 and 9 by the programmable circuitry platform 1700 of FIG. 17. The example machine-readable instructions or the example operations 1508 of FIG. 16 begin, for each signal statistics from the signal statistics generator circuitry 304 (blocks 1602-1612), at block 1604, at which the pre-combiner circuitry 902 multiplies and accumulates DPD estimation values from the DPD estimator circuitry 132 with slow signal statistics from the decimation circuitry 802. At block 1606, the modulus circuitry 904 generates a modulus input signal based on the input data signal. For example, the modulus circuitry 904 takes the modulus or absolute value of the input data signal to generate the modulus input signal.

At block 1608, the lookup table 906 generates a basis function data signal based on the modulus input data signal. For example, the lookup table 906 obtains the modulus input data signal and outputs a corresponding output that is a basis function data signal that corresponds to the modulus input signal. At block 1610, the multiplier circuitry 908 generates a first product based on the basis function data signal and the multiply and accumulate output.

At block 1614, the summation circuitry 918 generates a sum by summing the first products generated by the multiplication circuitries corresponding to each signal statistic. For example, the summation circuitry 918 can sum the output of the multiplier circuitry 908 for the first signal statistic and the output of the multiplier circuitry 916 for the Lth signal statistic. At block 1616, the multiplier circuitry 920 generates a slow dynamic term based on a product of the input signal and the sum. For example, the multiplier circuitry 920 multiplies the input signal x(n) by the sum generated by the summation circuitry 918. After block 1616, control returns to block 1510 of FIG. 15. FIGS. 15 and 16 correspond to processing an input signal and performing a DPD correction with respect to the input signal to mitigate nonlinearity at the output of the PA 116 of FIG. 1. In some examples, FIGS. 15 and 16 can additionally or alternatively be described in conjunction with lagged DPD terms using the example circuitries 1200, 1300 of FIGS. 12 and 13, as further described above.

FIG. 17 is a block diagram of an example programmable circuitry platform 1700 structured to execute or instantiate the example machine-readable instructions or the example operations of FIGS. 5, 7, 15, and 16 to implement the any of the circuitries 100, 200, 300, 400, 600, 800, 900, 1000, 1100, 1200, 1400 of FIGS. 1-4B, 6A, 6B, and 8-17. The programmable circuitry platform 1700 can be, for example, a server, a personal computer, a workstation, a self-learning machine (e.g., a neural network), a mobile device (e.g., a cell phone, a smart phone, a tablet such as an iPad™), or any other type of computing or electronic device.

The programmable circuitry platform 1700 of the illustrated example includes programmable circuitry 1712. The programmable circuitry 1712 of the illustrated example is hardware. For example, the programmable circuitry 1712 can be implemented by one or more integrated circuits, logic circuits, FPGAs, microprocessors, CPUs, GPUs, DSPs, or microcontrollers from any desired family or manufacturer. The programmable circuitry 1712 may be implemented by one or more semiconductor based (e.g., silicon based) devices. In this example, the programmable circuitry 1712 implements circuitry 100 or the DPD corrector circuitry 108 of FIGS. 1-4B, 6A, 6B, and 8-14.

The programmable circuitry 1712 of the illustrated example includes a local memory 1713 (e.g., a cache, registers, etc.). The programmable circuitry 1712 of the illustrated example is in communication with main memory 1714, 1716, which includes a volatile memory 1714 and a non-volatile memory 1716, by a bus 1718. The volatile memory 1714 may be implemented by Synchronous Dynamic Random Access Memory (SDRAM), Dynamic Random Access Memory (DRAM), RAMBUS® Dynamic Random Access Memory (RDRAM®), or any other type of RAM device. The non-volatile memory 1716 may be implemented by flash memory or any other desired type of memory device. Access to the main memory 1714, 1716 of the illustrated example is controlled by a memory controller 1717. In some examples, the memory controller 1717 may be implemented by one or more integrated circuits, logic circuits, microcontrollers from any desired family or manufacturer, or any other type of circuitry to manage the flow of data going to and from the main memory 1714, 1716.

The programmable circuitry platform 1700 of the illustrated example also includes interface circuitry 1720. The interface circuitry 1720 may be implemented by hardware in any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1722 are connected to the interface circuitry 1720. The input device(s) 1722 permit(s) a user (e.g., a human user, a machine user, etc.) to enter data or commands into the programmable circuitry 1712. The input device(s) 1722 can be implemented by, for example, an audio sensor, a microphone, a camera (still or video), a keyboard, a button, a mouse, a touchscreen, or a voice recognition system.

One or more output devices 1724 are also connected to the interface circuitry 1720 of the illustrated example. The output device(s) 1724 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, or speaker. The interface circuitry 1720 of the illustrated example, thus, typically includes a graphics driver card, a graphics driver chip, or graphics processor circuitry such as a GPU.

The interface circuitry 1720 of the illustrated example also includes a communication device such as a transmitter, a receiver, a transceiver, a modem, a residential gateway, a wireless access point, or a network interface to facilitate exchange of data with external machines (e.g., computing devices of any kind) by a network 1726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1700 of the illustrated example also includes one or more mass storage discs or devices 1728 to store firmware, software, or data. Examples of such mass storage discs or devices 1728 include magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices or SSDs.

The machine readable instructions 1732, which may be implemented by the machine readable instructions of FIGS. 5, 7, 15, and 16, may be stored in the mass storage device 1728, in the volatile memory 1714, in the non-volatile memory 1716, or on at least one non-transitory computer readable storage medium such as a CD or DVD which may be removable.

While an example manner of implementing the circuitry 100 of FIG. 1 is illustrated in FIGS. 2-4B, 6A, 6B, and 8-14, one or more of the elements, processes, or devices illustrated in FIGS. 2-4B, 6A, 6B, and 8-14 may be combined, divided, re-arranged, omitted, eliminated, or implemented in any other way. Further, any one or more of the components of FIGS. 1-4B, 6A, 6B, and 8-14 may be implemented by hardware alone or by hardware in combination with software and firmware. Thus, for example, any one or more of the components of FIGS. 1-4B, 6A, 6B, and 8-14, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example circuitry 100 of FIGS. 1-4B, 6A, 6B, and 8-14 may include one or more elements, processes, or devices in addition to, or instead of, those illustrated in FIGS. 1-4B, 6A, 6B, and 8-14, or may include more than one of any or all of the illustrated elements, processes and devices.

Flowchart(s) representative of example machine-readable instructions, which may be executed by programmable circuitry to at least one of implement or instantiate the components of FIGS. 1-4B, 6A, 6B, and 8-14 or representative of example operations which may be performed by programmable circuitry to at least one of implement or instantiate the components of FIGS. 1-4B, 6A, 6B, and 8-14, are shown in FIGS. 5, 7, 15, and 166. The machine-readable instructions may be one or more executable programs or portion(s) of one or more executable programs for execution by programmable circuitry such as the programmable circuitry 1712 shown in the example processor platform 1700 discussed below in connection with FIG. 17 and may be one or more function(s) or portion(s) of functions to be performed by the example programmable circuitry (e.g., an FPGA). In some examples, the machine-readable instructions cause an operation, a task, etc., to be carried out or performed in an automated manner in the real-world. As used herein, “automated” means without human involvement.

The program may be embodied in instructions (e.g., software or firmware) stored on one or more non-transitory computer readable or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4, 5, 15, and 16, many other methods of implementing the example circuitry 100 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts if decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 5, 7, 15, and 16 may be implemented using executable instructions (e.g., computer readable or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, if the phrase “at least” is used as the transition term in, for example, a preamble of a claim, it is open-ended in the same manner as the term “comprising” and “including” are open ended. The term “or” if used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part if the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Example methods, apparatus, systems, and articles of manufacture for dynamic digital pre-distortion correction are described herein. Further examples and combinations thereof include the following: Example 1 includes an apparatus comprising signal statistics generator circuitry having an input, a first output, and a second output, decimation circuitry having an input and an output, the input of the decimation circuitry is coupled to the first output of the signal statistics generator circuitry, first dynamics term generator circuitry having a first input, a second input, and an output, the first input of the first dynamics term generator circuitry coupled to the output of the decimation circuitry, the second input coupled to the input of the signal statistics generator circuitry, second dynamics term generator circuitry having a first input a second input and an output, the first input coupled to the second output of the signal statistics generator circuitry, the second input coupled to the input of the signal statistics generator circuitry, and summation circuitry having a first input and a second input, the first input coupled to the output of the first dynamics term generator circuitry, the second input coupled to the output of the second dynamics term generator circuitry.

Example 2 includes the apparatus of example 1, further including a host device, the input of the signal statistic generator circuitry is coupled to the host device.

Example 3 includes the apparatus of example 1, further including a power amplifier and a digital-to-analog converter, wherein the summation circuitry includes an output terminal that is coupled to the power amplifier via the digital-to-analog converter.

Example 4 includes the apparatus of example 1, wherein the first dynamics term generator circuitry includes a counter having a first output and a second output, the first output of the counter coupled to the decimation circuitry, pre-combining circuitry having a first input, a second input, and a third input, the first input of the pre-combining circuitry coupled to the counter, the second input of the pre-combining circuitry coupled to the output of the decimation circuitry, the third input coupled to a feedback loop, modulus circuitry having an input and an output, the input of the modulus circuitry coupled to the input of the signal statistics generator circuitry, a lookup table having an input and an output, the input of the lookup table coupled to the output of the modulus circuitry, and multiplier circuitry having a first input, a second input, and an output, the first input of the multiplier circuitry is coupled to the output of the pre-combining circuitry, the second input of the multiplier circuitry coupled to the output of the lookup table.

Example 5 includes the apparatus of example 4, wherein the multiplier circuitry is first multiplier circuitry and the summation circuitry is first summation circuitry, further including third dynamics term generator circuitry having a first input, a second input, a third input, and an output, the first input of the third dynamic term generator circuitry coupled to the output of the counter, the second input of the third dynamic term generator circuitry coupled to the second input of the pre-combining circuitry and the output of the decimation circuitry, the third input of circuitry coupled to the feedback loop, the output, and second summation circuitry having a first input, a second input, and an output, the first input of the second summation circuitry coupled to the output of the multiplier circuitry, the second input of the second summation circuitry coupled to the output of the third dynamics term generator circuitry, and second multiplier circuitry having a first input, a second input, and an output, the first input of the second multiplier circuitry coupled to the output of the second summation circuitry, the second input of the second multiplier circuitry coupled to the input of the signal statistics generator circuitry.

Example 6 includes the apparatus of example 5, wherein the input of the signal statistics generator circuitry is coupled to a storage device that stores a previous input data signal.

Example 7 includes the apparatus of example 4, wherein the decimation circuitry includes outputs including the output of the decimation circuitry and the multiplier circuitry is first multiplier circuitry, the pre-combining circuitry including a first multiplexer having inputs, a select input and an output, the inputs of the first multiplexer coupled to the outputs of the decimation circuitry, the select input of the first multiplexer coupled to the second output of the counter, a buffer having an input and an output, the input of the buffer coupled to the second output of the counter, second multiplier circuitry having a first input, a second input, and an output, the first input of the second multiplier circuitry coupled to the output of the first multiplexer, the second input of the second multiplier circuitry coupled to the output of the buffer, third summation circuitry having a first input, a second input, and an output, the first input of the third summation circuitry coupled to the output of the second multiplier circuitry, a first register including an input and an output, the input of the first register coupled to the output of the third summation circuitry, and a second multiplexer having a first data input, a second data input, a select input, and an output, the first data input of the second multiplexer coupled to the output of the first register, the second data input of the second multiplexer coupled to a common terminal, the select input of the second multiplexer coupled to the first output of the counter, the output of the second multiplexer coupled to the second input of the third summation circuitry.

Example 8 includes the apparatus of example 7, wherein the pre-combining circuitry further includes a third multiplexer having a first data input, a second data input, a select input, and an output, the first data input coupled to the output of the first register and the first data input of the second multiplexer, the select input of the third multiplexer coupled to the first output of the counter, and a second register including an input and an output, the input of the second register coupled to the output of the third multiplexer, the output of the second register coupled to the second data input of the third multiplexer and the first input of the first summation circuitry.

Example 9 includes the apparatus of example 1, wherein the signal statistics generator circuitry has outputs including the first output and the second output, the second dynamics term generator circuitry including modulus circuitry having an input and an output, the input of the modulus circuitry coupled to the input of the signal statistic generator circuitry, a first lookup table having an input and an output, the input of the first lookup table coupled to the output of the modulus circuitry, and first multiplier circuitry having a first input, a second input, and an output, the first input of the first multiplier circuitry coupled to the output of the first lookup table, the second input of the first multiplier circuitry coupled to the second output of the signal statistics generator circuitry.

Example 10 includes the apparatus of example 9, wherein the summation circuitry is first summation circuitry, the second dynamics term generator circuitry further including a second lookup table having an input and an output, the input of the second lookup table coupled to the output of the modulus circuitry, second multiplier circuitry having a first input, a second input, and an output, the first input of the second multiplier circuitry coupled to the output of the second lookup table, the second input of the second multiplier circuitry coupled to a third output of the outputs of the signal statistics generator circuitry, second summation circuitry having a first input, a second input, and an output, the first input of the second summation circuitry coupled to the output of the first multiplier circuitry, the second input of the second summation circuitry coupled to the output of the second multiplier circuitry, and third multiplier circuitry having a first input, a second input, and an output, the first input of the third multiplier circuitry coupled to the output of the second summation circuitry, the second input of the third multiplier circuitry coupled to the input of the signal statistics generator circuitry, the output of the third multiplier circuitry coupled to the second input of the first summation circuitry.

Example 11 includes the apparatus of example 10, wherein the input of the signal statistics generator circuitry is coupled to a storage device that stores a previous input data signal.

Example 12 includes the apparatus of example 1, wherein the decimation circuitry is first decimation circuitry, the signal statistics generator circuitry including mapping function circuitry including an input and an output, the input of the mapping function circuitry being the input of the signal statistics generator circuitry, decimation logic circuitry having an input and an output, the input of the decimation logic circuitry coupled to the output of the mapping function circuitry, second decimation circuitry having an input and an output, the input of the second decimation circuitry coupled to the output of the decimation logic circuitry, and statistic generator circuitry including an input and an output, the input of the statistic generator circuitry coupled to the output of the second decimation circuitry, the output of the statistic generator circuitry coupled to the input of the first decimation circuitry.

Example 13 includes an apparatus comprising, memory, and programmable circuitry operable to execute computer readable instructions to at least generate signal statistics based on an input signal, group the signal statistics into a first group of signal statistics or a second group of signal statistics based on time constants of the signal statistics, decimate the first group of signal statistics, generate a first predistortion term based on the decimated first group of signal statistics, generate a second predistortion term based on the second group of signal statistics, and generate an output predistortion terminal based on the first predistortion term and the second predistortion term.

Example 14 includes the apparatus of example 13, wherein the first group of signal statistics are signal statistics with time constants below a threshold and the second group of signal statistics are signal statistics with time constant above the threshold.

Example 15 includes the apparatus of example 13, wherein the programmable circuitry is operable to generate the first predistortion term by generate pre-combination terms based on a multiplications and accumulations of predistortion estimation terms and the first group of signal statistics, determine a modulus of the input signal, generate basis function outputs based on basis functions of the modulus of the input signal, multiply the basis function outputs by the pre-combination terms to generate weighted envelopes, sum the weighted envelopes, and multiply the input signal by the sum.

Example 16 includes the apparatus of example 13, wherein the programmable circuitry is operable to generate the second predistortion term by determine a modulus of the input signal, generate basis function outputs based on basis functions of the modulus of the input signal, multiply the basis function outputs by the second group of signal statistics to generate products, sum the products, and multiply the input signal by the product.

Example 17 includes a wireless transmitter comprising a host device having an output, interpolation circuitry having an input and an output, the input of the interpolation circuitry coupled to the output of the host device, a predistortion correction circuitry including signal statistics generator circuitry having an input, a first output, and a second output, the input of the signal statistics generator circuitry coupled to the output of the interpolation circuitry, decimation circuitry having an input and an output, the input of the decimation circuitry is coupled to the first output of the signal statistics generator circuitry, first dynamics term generator circuitry having a first input, a second input, and an output, the first input of the first dynamics term generator circuitry coupled to the output of the decimation circuitry, the second input coupled to the input of the signal statistics generator circuitry, second dynamics term generator circuitry having a first input a second input and an output, the first input coupled to the second output of the signal statistics generator circuitry, the second input coupled to the input of the signal statistics generator circuitry, and summation circuitry having a first input, a second input, and an output, the first input coupled to the output of the first dynamics term generator circuitry, the second input coupled to the output of the second dynamics term generator circuitry, digital circuitry having an input and an output, the input of the digital circuitry coupled to the output of the summation circuitry, a digital-to-analog converter having an input and an output, the input of the digital-to-analog converter coupled to the output of the digital circuitry, and a power amplifier having an input and an output, the input of the power amplifier coupled to the output of the digital-to-analog converter.

Example 18 includes the wireless transmitter of example 17, further including an analog-to-digital converter having an input and an output, the input of the analog-to-digital converter coupled to the output of the power amplifier, and a predistortion estimator circuitry having an input and an output, the input of the predistortion estimator circuitry coupled to the output of the analog-to-digital converter.

Example 19 includes the wireless transmitter of example 18, wherein the input of the predistortion estimator circuitry is coupled to the output of the analog-to-digital converter via at least one of digital feedback circuitry or capture subsystem circuitry.

Example 20 includes the wireless transmitter of example 17, further including an antenna having an input, the input of the antenna coupled to the output of the power amplifier.

Modifications are possible in the described examples, and other examples are possible, within the scope of the claims.

What is claimed is:

1. An apparatus comprising:
signal statistics generator circuitry having an input, a first output, and a second output;
decimation circuitry having an input and an output, the input of the decimation circuitry is coupled to the first output of the signal statistics generator circuitry;
first dynamics term generator circuitry having a first input, a second input, and an output, the first input of the first dynamics term generator circuitry coupled to the output of the decimation circuitry, the second input coupled to the input of the signal statistics generator circuitry;
second dynamics term generator circuitry having a first input, a second input and an output, the first input coupled to the second output of the signal statistics generator circuitry, the second input coupled to the input of the signal statistics generator circuitry; and
summation circuitry having a first input and a second input, the first input coupled to the output of the first dynamics term generator circuitry, the second input coupled to the output of the second dynamics term generator circuitry.

2. The apparatus of claim 1, further including a host device, the input of the signal statistic generator circuitry is coupled to the host device.

3. The apparatus of claim 1, further including a power amplifier and a digital-to-analog converter, wherein the summation circuitry includes an output terminal that is coupled to the power amplifier via the digital-to-analog converter.

4. The apparatus of claim 1, wherein the first dynamics term generator circuitry includes first dynamics term generator sub-circuitry including:
a counter having a first output and a second output, the first output of the counter coupled to the decimation circuitry;
pre-combining circuitry having a first input, a second input, and a third input, the first input of the pre-combining circuitry coupled to the counter, the second input of the pre-combining circuitry coupled to the output of the decimation circuitry, the third input coupled to a feedback loop;
modulus circuitry having an input and an output, the input of the modulus circuitry coupled to the input of the signal statistics generator circuitry;
a lookup table having an input and an output, the input of the lookup table coupled to the output of the modulus circuitry; and
multiplier circuitry having a first input, a second input, and an output, the first input of the multiplier circuitry is coupled to the output of the pre-combining circuitry, the second input of the multiplier circuitry coupled to the output of the lookup table.

5. The apparatus of claim 4, wherein the multiplier circuitry is first multiplier circuitry and the summation circuitry is first summation circuitry, further including:
second dynamics term generator sub-circuitry having a first input, a second input, a third input, and an output, the first input of the second dynamics term generator sub-circuitry coupled to the output of the counter, the second input of the second dynamics term generator sub-circuitry coupled to the second input of the pre-combining circuitry and the output of the decimation circuitry, the third input of circuitry coupled to the feedback loop, the output; and
second summation circuitry having a first input, a second input, and an output, the first input of the second summation circuitry coupled to the output of the multiplier circuitry, the second input of the second summation circuitry coupled to the output of the second dynamics term generator sub-circuitry; and
second multiplier circuitry having a first input, a second input, and an output, the first input of the second multiplier circuitry coupled to the output of the second summation circuitry, the second input of the second multiplier circuitry coupled to the input of the signal statistics generator circuitry.

6. The apparatus of claim 5, wherein the input of the signal statistics generator circuitry is coupled to a storage device that stores a previous input data signal.

7. The apparatus of claim 4, wherein the decimation circuitry includes outputs including the output of the decimation circuitry, the multiplier circuitry is first multiplier circuitry, and the lookup table is a first lookup table, the pre-combining circuitry including:
a first multiplexer having inputs, a select input and an output, the inputs of the first multiplexer coupled to the outputs of the decimation circuitry, the select input of the first multiplexer coupled to the second output of the counter;
a second lookup table having an input and an output, the input of the second lookup table coupled to the second output of the counter;
second multiplier circuitry having a first input, a second input, and an output, the first input of the second multiplier circuitry coupled to the output of the first multiplexer, the second input of the second multiplier circuitry coupled to the output of the second lookup table;
third summation circuitry having a first input, a second input, and an output, the first input of the third summation circuitry coupled to the output of the second multiplier circuitry;
a first register including an input and an output, the input of the first register coupled to the output of the third summation circuitry; and
a second multiplexer having a first data input, a second data input, a select input, and an output, the first data input of the second multiplexer coupled to the output of the first register, the second data input of the second multiplexer coupled to a common terminal, the select input of the second multiplexer coupled to the first output of the counter, the output of the second multiplexer coupled to the second input of the third summation circuitry.

8. The apparatus of claim 7, wherein the summation circuitry is first summation circuitry, the pre-combining circuitry further including:
a third multiplexer having a first data input, a second data input, a select input, and an output, the first data input coupled to the output of the first register and the first data input of the second multiplexer, the select input of the third multiplexer coupled to the first output of the counter; and
a second register including an input and an output, the input of the second register coupled to the output of the third multiplexer, the output of the second register coupled to the second data input of the third multiplexer and the first input of the first summation circuitry.

9. The apparatus of claim 1, wherein the signal statistics generator circuitry has outputs including the first output and the second output, the second dynamics term generator circuitry including:
modulus circuitry having an input and an output, the input of the modulus circuitry coupled to the input of the signal statistic generator circuitry;
a first lookup table having an input and an output, the input of the first lookup table coupled to the output of the modulus circuitry; and
first multiplier circuitry having a first input, a second input, and an output, the second input of the first multiplier circuitry coupled to the output of the first lookup table.

10. The apparatus of claim 9, wherein the summation circuitry is first summation circuitry, the second dynamics term generator circuitry further including:
a second lookup table having an input and an output, the input of the second lookup table coupled to the output of the modulus circuitry;
second multiplier circuitry having a first input, a second input, and an output, the first input of the second multiplier circuitry coupled to the output of the second lookup table, the second input of the second multiplier circuitry coupled to a third output of the outputs of the signal statistics generator circuitry;
second summation circuitry having a first input, a second input, and an output, the first input of the second summation circuitry coupled to the output of the first multiplier circuitry, the second input of the second summation circuitry coupled to the output of the second multiplier circuitry; and
third multiplier circuitry having a first input, a second input, and an output, the first input of the third multiplier circuitry coupled to the output of the second summation circuitry, the second input of the third multiplier circuitry coupled to the input of the signal statistics generator circuitry, the output of the third multiplier circuitry coupled to the second input of the first summation circuitry.

11. The apparatus of claim 10, wherein the input of the signal statistics generator circuitry is coupled to a storage device that stores a previous input data signal.

12. The apparatus of claim 1, wherein the decimation circuitry is first decimation circuitry, the signal statistics generator circuitry including:
mapping function circuitry including an input and an output, the input of the mapping function circuitry being the input of the signal statistics generator circuitry;
decimation logic circuitry having an input and an output, the input of the decimation logic circuitry coupled to the output of the mapping function circuitry;
second decimation circuitry having an input and an output, the input of the second decimation circuitry coupled to the output of the decimation logic circuitry; and
statistic generator circuitry including an input and an output, the input of the statistic generator circuitry coupled to the output of the second decimation circuitry, the output of the statistic generator circuitry coupled to the input of the first decimation circuitry.

13. An apparatus comprising;
memory; and
programmable circuitry operable to execute computer readable instructions to at least:
generate signal statistics based on an input signal;
group the signal statistics into a first group of signal statistics or a second group of signal statistics based on time constants of the signal statistics;
decimate the first group of signal statistics;
generate a first predistortion term based on the decimated first group of signal statistics;
generate a second predistortion term based on the second group of signal statistics; and
generate an output predistortion terminal based on the first predistortion term and the second predistortion term.

14. The apparatus of claim 13, wherein the first group of signal statistics are signal statistics with time constants below a threshold and the second group of signal statistics are signal statistics with time constant above the threshold.

15. The apparatus of claim 14, wherein the programmable circuitry is operable to generate the first predistortion term by:
generate pre-combination terms based on a multiplications and accumulations of predistortion estimation terms and the first group of signal statistics;
determine a modulus of the input signal;
generate basis function outputs based on basis functions of the modulus of the input signal;
multiply the basis function outputs by the pre-combination terms to generate weighted envelopes;
sum the weighted envelopes; and
multiply the input signal by the sum.

16. The apparatus of claim 15, wherein the programmable circuitry is operable to generate the second predistortion term by:
determine a modulus of the input signal;
generate non-linear function of the modulus of the input signal based on digital predistortion estimated coefficients;
multiply the basis function outputs by the second group of signal statistics to generate products;
sum the products; and
multiply the input signal by the product.

17. A wireless transmitter comprising:
a host device having an output;
interpolation circuitry having an input and an output, the input of the interpolation circuitry coupled to the output of the host device;
a predistortion correction circuitry including:
signal statistics generator circuitry having an input, a first output, and a second output, the input of the signal statistics generator circuitry coupled to the output of the interpolation circuitry;
decimation circuitry having an input and an output, the input of the decimation circuitry is coupled to the first output of the signal statistics generator circuitry;
first dynamics term generator circuitry having a first input, a second input, and an output, the first input of the first dynamics term generator circuitry coupled to the output of the decimation circuitry, the second input coupled to the input of the signal statistics generator circuitry;
second dynamics term generator circuitry having a first input a second input and an output, the first input coupled to the second output of the signal statistics generator circuitry, the second input coupled to the input of the signal statistics generator circuitry; and
summation circuitry having a first input, a second input, and an output, the first input coupled to the output of the first dynamics term generator circuitry, the second input coupled to the output of the second dynamics term generator circuitry;
digital circuitry having an input and an output, the input of the digital circuitry coupled to the output of the summation circuitry;
a digital-to-analog converter having an input and an output, the input of the digital-to-analog converter coupled to the output of the digital circuitry; and
a power amplifier having an input and an output, the input of the power amplifier coupled to the output of the digital-to-analog converter.

18. The wireless transmitter of claim 17, further including:
an analog-to-digital converter having an input and an output, the input of the analog-to-digital converter coupled to the output of the power amplifier; and
a predistortion estimator circuitry having an input and an output, the input of the predistortion estimator circuitry coupled to the output of the analog-to-digital converter.

19. The wireless transmitter of claim 18, wherein the input of the predistortion estimator circuitry is coupled to the output of the analog-to-digital converter via at least one of digital feedback circuitry or capture subsystem circuitry.

20. The wireless transmitter of claim 17, further including an antenna having an input, the input of the antenna coupled to the output of the power amplifier.
